(19) United States
(12) Patent Application Publication
(10) Pub. No.: US 2026/0262359 A1
(43) Pub. Date: Sep. 3, 2026

(54) Light-Emitting Module and Assembling Method Therefor, and Display Apparatus

(71) Applicants: HEFEI BOE OPTOELECTRONICS TECHNOLOGY CO., LTD., Hefei, Anhui (CN); BOE TECHNOLOGY GROUP CO., LTD., Chaoyang District, Beijing (CN)

(72) Inventors: Dong Chang, Beijing (CN); Jun Shao, Beijing (CN); Bangmin Chen, Beijing (CN); Hanqi Chu, Beijing (CN)

(21) Appl. No.: 18/993,774

(22) PCT Filed: Mar. 31, 2023
(86) PCT No.: PCT/CN2023/085621

§ 371 Date: Jan. 13, 2025

(51) Int. Cl. H10H 29/856; G02B 5/08

(52) U.S. Cl. CPC H10H 29/856; G02B 5/08

(57) ABSTRACT

A light-emitting module (40). The light-emitting module (40) comprises a substrate (410), a plurality of light-emitting devices (420), an optical film (G) and a light-reflecting structure (440), wherein the plurality of light-emitting devices (420) are arranged on the substrate (410) and are configured to emit light to one side away from the substrate (410); the optical film (G) is arranged on the side of the plurality of light-emitting devices (420) away from the substrate (410); and the light-reflecting structure (440) is arranged on the optical film (G), and the light-reflecting structure (440) comprises a plurality of light-reflecting units (441). The light-reflecting unit (441) comprises a first light-reflecting pattern (4411) and at least one second light-reflecting pattern (4412), wherein at least part of the first light-reflecting pattern (4411) is arranged around the at least one second light-reflecting pattern (4412); the reflectivity of the second light-reflecting pattern (4412) is greater than or equal to the reflectivity of the first light-reflecting pattern (4411); there is an overlapping area between the orthographic projection of the second light-reflecting pattern (4412) on the substrate (410) and the orthographic projection of the light-emitting device (420) on the substrate (410), and the second light-reflecting pattern (4412) is configured to reflect light emitted by the light-emitting device (420); and the first light-reflecting pattern (4411) is configured to reflect the light emitted by the light-emitting device (420).

### TECHNICAL FIELD

The present disclosure relates to the field of display technologies, and in particular, to a light-emitting module and an assembling method therefor, and a display apparatus.

### BACKGROUND

A display apparatus (e.g., a liquid crystal display apparatus) includes a display module (e.g., a liquid crystal display module) and a backlight module. The backlight module is disposed on a non-display surface of the liquid crystal display module. The backlight module may include light-emitting devices that provide backlight for the non-display surface of the liquid crystal display panel. In a case where the light-emitting devices are, for example, submillimeter light-emitting diodes (mini light-emitting diode, mini LED), in aspects of dynamic range, contrast, brightness, color gamut, viewing angle, etc., the display apparatus has various advantages such as high color gamut, high image quality, low power consumption and energy saving. Therefore, the market for mini LED display apparatuses is good.

### SUMMARY

In an aspect, a light-emitting module is provided. The light-emitting module includes a substrate, a plurality of light-emitting devices, an optical film and a reflective structure. The plurality of light-emitting devices are disposed on the substrate and configured to emit light toward a side away from the substrate. The optical film is disposed on a side of the plurality of light-emitting devices away from the substrate. The reflective structure is disposed on the optical film, and the reflective structure includes a plurality of reflective units. A reflective unit includes a first reflective pattern and at least one second reflective pattern; at least a portion of the first reflective pattern is arranged surrounding the at least one second reflective pattern; a reflectivity of a second reflective pattern is greater than or equal to a reflectivity of the first reflective pattern. An orthographic projection of the second reflective pattern on the substrate overlaps with an orthographic projection of a light-emitting device on the substrate, and the second reflective pattern is configured to reflect light emitted by the light-emitting device; the first reflective pattern is configured to reflect light emitted by the light-emitting device.

A part of the light emitted by the light-emitting device is reflected by the reflective structure and directed to the substrate, and then is reflected by the substrate and directed to a light projection region and a dark projection region, so that a luminance of the dark projection region is increased. In addition, another part of the light emitted by the light-emitting device passes through the reflective structure and is directed to the light projection region, which makes the luminance of light emitted by the light-emitting module substantially consistent, thereby alleviating the problem that the light emitted by the light-emitting module is not uniform.

The orthographic projection of the second reflective pattern on the substrate overlaps the orthographic projection of the light-emitting device on the substrate, so that light emitted by the light-emitting device with a relatively great luminous intensity illuminates the second reflective pattern and forms reflected light (recorded as first reflected light), and light emitted by the light-emitting device with a relatively less luminous intensity illuminates the first reflective pattern and forms reflected light (recorded as second reflected light). The reflectivity of the first reflective pattern is less than the reflectivity of the second reflective pattern. As a result, the second reflective pattern reflects more light that is emitted by the light-emitting device, and the first reflective pattern reflects less light that is emitted by the light-emitting device. In this way, the first reflected light with greater luminous intensity and larger quantity may be formed on the second reflective pattern, and the second reflected light with less luminous intensity and less quantity may be formed on the first reflective pattern; the first reflected light and the second reflected light may propagate to the light projection region and the dark projection region, so that the luminance of the dark projection region is increased. Compared with a situation where the reflectivity of the reflective structure is the same everywhere, in the embodiments of the present disclosure, the luminance uniformity of the dark projection region and the light projection region is better.

Optionally, a transmittance of the second reflective pattern is less than a transmittance of the first reflective pattern.

Optionally, the light-emitting module has a plurality of light projection regions; a light projection region is a region in a plane where the reflective structure is located and illuminated by light emitted by the light-emitting device. The second reflective pattern is located in the light projection region, and at least a portion of the first reflective pattern is located in the light projection region.

Optionally, the second reflective pattern covers a geometric center region of the light projection region.

Optionally, the reflective unit includes a second reflective pattern; in the reflective unit, the first reflective pattern is located in the light projection region.

Optionally, the reflective unit includes a plurality of second reflective patterns; in the reflective unit, the first reflective pattern includes a plurality of first portions and a second portion; a first portion is located in the light projection region and arranged surrounding a second reflective pattern; the second portion is located outside the light projection region and connected to the plurality of first portions.

Optionally, the first reflective pattern has at least one hollow region, and the second reflective pattern is disposed in a hollow region.

Optionally, the first reflective pattern and the second reflective pattern are stacked; the second reflective pattern is closer to the substrate than the first reflective pattern. The first reflective pattern includes a first sub-portion and a second sub-portion; an orthographic projection of the first sub-portion on the substrate coincides with an orthographic projection of the second reflective pattern on the substrate; the second sub-portion is located outside the second reflective pattern and arranged surrounding the first sub-portion.

Optionally, the first reflective pattern includes a first central portion and a plurality of first radiating portions, the first central portion is arranged surrounding the second reflective pattern, and the plurality of first radiating portions are circumferentially arranged around the first central portion.

Optionally, a number of the plurality of first radiating portions is greater than or equal to five.

Optionally, a reflectivity of the first central portion is greater than or equal to a reflectivity of a first radiating portion.

Optionally, the second reflective pattern includes a second central portion and a plurality of second radiating portions, and the plurality of second radiating portions are circumferentially arranged around the second central portion.

Optionally, a reflectivity of the second central portion is greater than or equal to a reflectivity of a second radiating portion.

Optionally, the first reflective pattern includes a plurality of first radiating portions; a number of the plurality of first radiating portions and a number of the plurality of second radiating portions are same; and extension directions of the first radiating portions are same as extension directions of the plurality of second radiating portions.

Optionally, the light-emitting device has a first edge extending in a first direction and a second edge extending in a second direction. In the reflective unit, the at least one second reflective pattern is arranged in an n*m array; n is a number of second reflective patterns included in each row in the first direction, and n is greater than or equal to 1; m is a number of second reflective patterns included in each column in the second direction, and m is greater than or equal to 1. A length L of the reflective unit in the first direction and a width W of the reflective unit in the second direction satisfy following formulas:

$$L = {nL}_{1} + 2 h tan ( θ - 90 ° ) + ( n - 1 ) {L}_{3} + {δ}_{l 2} ; and$$

$$W = m {W}_{1} + 2 h tan ( θ - 90 ° ) + ( m - 1 ) {W}_{3} + {δ}_{w 2} .$$

L₁ is a length of the light-emitting device in the first direction, W₁ is a width of the light-emitting device in the second direction; h is a distance between a plane where the light-emitting device is located and a plane where the reflective structure is located; θ is a light-emitting angle of the light-emitting device; L₃ is a distance between adjacent light-emitting devices in the first direction, W₃, is a distance between adjacent light-emitting devices in the second direction; δₗ₂ and δ_{w2} are constants.

Optionally, the first reflective pattern includes a first central portion and a plurality of first radiating portions; a first radiating portion has an end portion and a root portion, the root portion is disposed at the first central portion, and the end portion is an end of the root portion opposite to the first central portion. A length L₄ of the first central portion in the first direction and a width W₄ of the first central portion in the second direction satisfy following formulas:

$$\frac{1}{2} {L}_{1} \leq {L}_{4} \leq \frac{3}{4} {L}_{1} ; \frac{1}{2} {W}_{1} \leq {W}_{4} \leq \frac{3}{4} {W}_{1} .$$

A length L₅ of the second reflective pattern in the first direction and a width W₅ of the second reflective pattern in the second direction satisfy following formulas:

$$\frac{1}{3} {L}_{4} \leq {L}_{5} \leq \frac{3}{4} {L}_{4} ; \frac{1}{3} {W}_{4} \leq {W}_{5} \leq \frac{3}{4} {W}_{4} .$$

In a first radiating portion, a distance δₗ₄ between the end portion and the root portion in the first direction and a distance δ_{W4} between the end portion and the root portion in the second direction satisfy following formulas:

$${δ}_{l 4} = ( L - {L}_{4} ) / 2 ; {δ}_{W 4} = ( W - {W}_{4} ) / 2.$$

Optionally, an outer edge of the first reflective pattern is in a shape of an ellipse or a circle, and the outer edge of the first reflective pattern is an edge of the first reflective pattern away from the second reflective pattern.

Optionally, the second reflective pattern is in a shape of an ellipse or a circle.

Optionally, luminances of the plurality of light-emitting devices are controlled separately; the reflective unit includes a first reflective pattern and a second reflective pattern, and at least a portion of the first reflective pattern is arranged surrounding the second reflective pattern.

Optionally, the plurality of light-emitting devices are divided into a plurality of device groups, and a device group includes K light-emitting devices that are connected in series, and K is greater than 2. A device group corresponds to a reflective unit; the reflective unit includes a first reflective pattern and K second reflective patterns, and at least a portion of the first reflective pattern is arrange surrounding the K second reflective patterns; an orthographic projection of each second reflective pattern in the reflective unit on the substrate overlaps with an orthographic projection of a light-emitting device in a corresponding device group on the substrate.

Optionally, the plurality of light-emitting devices are divided into a plurality of device groups, and a device group includes K light-emitting devices that are connected in series, and K is greater than 2. A device group corresponds to K reflective units; a reflective unit includes a first reflective pattern and a second reflective pattern, and at least a portion of the first reflective pattern is arranged surrounding the second reflective pattern; an orthographic projection of a second reflective pattern included in each reflective unit of the K reflective units on the substrate overlaps with an orthographic projection of a light-emitting device in a corresponding device group on the substrate.

Optionally, the reflective structure is disposed on a side of the optical film proximate to the substrate.

Optionally, a density of the first reflective pattern is less than or equal to a density of the second reflective pattern.

Optionally, a thickness of the first reflective pattern is less than or equal to a thickness of the second reflective pattern.

Optionally, the first reflective pattern is made of a first ink, and the second reflective pattern is made of a second ink.

Optionally, the optical film is a diffusion film or a light-homogenizing film.

Optionally, the first reflective pattern includes a plurality of first reflective sub-patterns, and the plurality of first reflective sub-patterns are sequentially arranged surrounding the second reflective pattern; in a direction from the second reflective pattern to the first reflective pattern, transmittances of the plurality of first reflective sub-patterns decrease in sequence.

Optionally, the second reflective pattern includes a second reflective sub-pattern and at least one third reflective sub-pattern; the at least one third reflective sub-pattern is sequentially arranged surrounding the second reflective sub-pattern; in the direction from the second reflective pattern to the first reflective pattern, transmittances of the second reflective sub-pattern and the at least one third reflective sub-pattern decrease in sequence.

Optionally, the first reflective pattern includes a plurality of first reflective sub-patterns, and the plurality of first reflective sub-patterns are arranged surrounding the second reflective pattern in sequence; in the direction from the second reflective pattern to the first reflective pattern, transmittances of the plurality of first reflective sub-patterns decrease in sequence. The second reflective pattern includes a second reflective sub-pattern and at least one third reflective sub-pattern; the at least one third reflective sub-pattern is sequentially arranged surrounding the second reflective sub-pattern; in the direction from the second reflective pattern to the first reflective pattern, transmittances of the second reflective sub-pattern and the at least one third reflective sub-pattern decrease in sequence.

Optionally, the reflectivity of the second reflective pattern is in a range from 80% to 90%.

Optionally, the reflectivity of the first reflective pattern is in a range from 30% to 40%.

Optionally, the reflectivity of the second reflective pattern is in a range from 80% to 90%, and the reflectivity of the first reflective pattern is in a range from 30% to 40%.

In another aspect, an assembling method for a light-emitting module is provided, and the assembling method for the light-emitting module includes: providing a plurality of light-emitting devices on a substrate, the plurality of light-emitting devices being configured to emit light toward a side away from the substrate; providing an optical film on a side of the plurality of light-emitting devices away from the substrate; providing a reflective structure on the optical film, the reflective structure including a plurality of reflective units; a reflective unit including a first reflective pattern and at least one second reflective pattern, and at least a portion of the first reflective pattern being arranged by surrounding the at least one second reflective pattern; a reflectivity of a second reflective pattern being greater than a reflectivity of the first reflective pattern. An orthographic projection of the second reflective pattern on the substrate overlaps with an orthographic projection of a light-emitting device on the substrate, the second reflective pattern is configured to reflect light emitted by the light-emitting device, and the first reflective pattern is configured to reflect light emitted by the light-emitting device. The effects of the assembling method for the light-emitting module may refer to the relevant description of the effects of the light-emitting module, which will not be repeated here.

Optionally, before the step of providing the reflective structure on the optical film, the assembling method for the light-emitting module further includes: determining shapes of each second reflective pattern and a first reflective pattern in the reflective unit; based on the shape of the second reflective pattern and the shape of the first reflective pattern, a length L₁ of the light-emitting device in a first direction, a width W₁ of the light-emitting device in a second direction, a distance h between a plane where the light-emitting device is located and a plane where the reflective structure is located, a light-emitting angle θ of the light-emitting device, a distance L₃ between adjacent light-emitting devices in the first direction, and a distance W₃ between adjacent light-emitting devices in the second direction, determining a size of the second reflective pattern and a size of the first reflective pattern; and providing a first screen plate including a plurality of first openings and a second screen plate including a plurality of second openings; a shape and size of a first opening being determined based on the shape and size of the first reflective pattern, respectively, and a shape and size of a second opening being determined based on the shape and size of the second reflective pattern, respectively.

The step of providing the reflective structure on the optical film includes: forming a plurality of first reflective patterns on the optical film by using the plurality of first openings of the first screen plate; and forming a plurality of second reflective patterns on the optical film by using the plurality of second openings of the second screen plate.

In yet another aspect, a display apparatus is provided. The display apparatus includes the above-mentioned light-emitting module; therefore, the display apparatus has the same effect as the light-emitting module has, which will not be repeated here.

### BRIEF DESCRIPTION OF THE DRAWINGS

In order to describe technical solutions in the present disclosure more clearly, the accompanying drawings to be used in some embodiments of the present disclosure will be introduced briefly below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus according to some embodiments;

FIG. 2 is a structural diagram of a light-emitting module (without a reflective structure) according to some embodiments;

FIG. 3 is a simulation diagram of a light projection region according to some embodiments;

FIG. 4A is a structural diagram of a light-emitting module (provided with a reflective structure) according to some embodiments;

FIG. 4B is a structural diagram of another light-emitting module (provided with a reflective structure) according to some embodiments;

FIG. 5A is real picture of a reflective structure according to some embodiments;

FIG. 5B is a structural diagram of a reflective unit according to some embodiments;

FIG. 6 is a sectional view taken along the line A-A in FIG. 5B;

FIG. 7 is another sectional view taken along the line A-A in FIG. 5B;

FIG. 8 is a structural diagram of a light-emitting module in a comparative solution;

FIG. 9 is a structural diagram of a reflective unit according to some embodiments;

FIG. 10A is a structural diagram of another reflective unit according to some embodiments;

FIG. 10B is a structural diagram of yet another reflective unit according to some embodiments;

FIG. 11 is a structural diagram of reflective units and an optical film according to some embodiments;

FIG. 12 is a structural diagram replacing the region Q in FIG. 4A;

FIG. 13 is an enlarged view of the region P in FIG. 12;

FIG. 14 is a structural diagram of another reflective unit according to some embodiments;

FIG. 15 is a structural diagram replacing the region Q in FIG. 4A;

FIG. 16 is a structural diagram of yet another reflective unit according to some embodiments;

FIG. 17 is a structural diagram replacing the region Q in FIG. 4A;

FIG. 18 is a structural diagram of multiple reflective units according to some embodiments;

FIG. 19 is another structural diagram of multiple reflective units according to some embodiments;

FIG. 20 is a flow diagram of an assembling method for a light-emitting module according to some embodiments;

FIG. 21 is a structural diagram of a first reflective pattern fabricated by using a first screen plate; and

FIG. 22 is a structural diagram of a second reflective pattern fabricated by using a second screen plate.

### DETAILED DESCRIPTION

The technical solutions in embodiments of the present disclosure will be described clearly and completely with reference to the accompanying drawings. Obviously, the described embodiments are merely some but not all of embodiments of the present disclosure. All other embodiments obtained based on the embodiments of the present disclosure by a person of ordinary skill in the art shall belong to the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” and “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the said specific features, structures, materials, or characteristics described herein may be included in any one or more embodiments or examples in any suitable manner.

Hereinafter, the terms such as “first” and “second” are used for descriptive purpose only, but are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of/the plurality of” means two or more unless otherwise specified.

Some embodiments may be described using the terms “couple” and “connect” or their derivatives. The term “connect” should be understood in a broad sense. For example, “connection” can be a fixed connection, a detachable connection, or a one-piece connection; it can be a direct connection or an indirect connection through an intermediate medium. The term “coupled” indicates, for example, that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value, the acceptable range of deviation is determined, for example, by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation, the acceptable range of deviation is determined, for example, by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It should be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that serve as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including variations in shape due to, for example, manufacturing. For example, an etched region shown in a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

Some embodiments of the present disclosure provide a display apparatus. The display apparatus 1 is a product having an image (including static images or moving images, where the moving images may be a video) display function. The display apparatus 1 may be, for example, a virtual reality (VR) display device, an augmented reality (AR) display device, a monitor, a mobile phone, a tablet computer (Pad), a notebook computer, a television, a personal digital assistant (PDA), an ultra-mobile personal computer (UMPC), a netbook, a wearable device (e.g., a smart watch) or a vehicle-mounted display device 1, and the type of the display apparatus 1 is not limited in the embodiments.

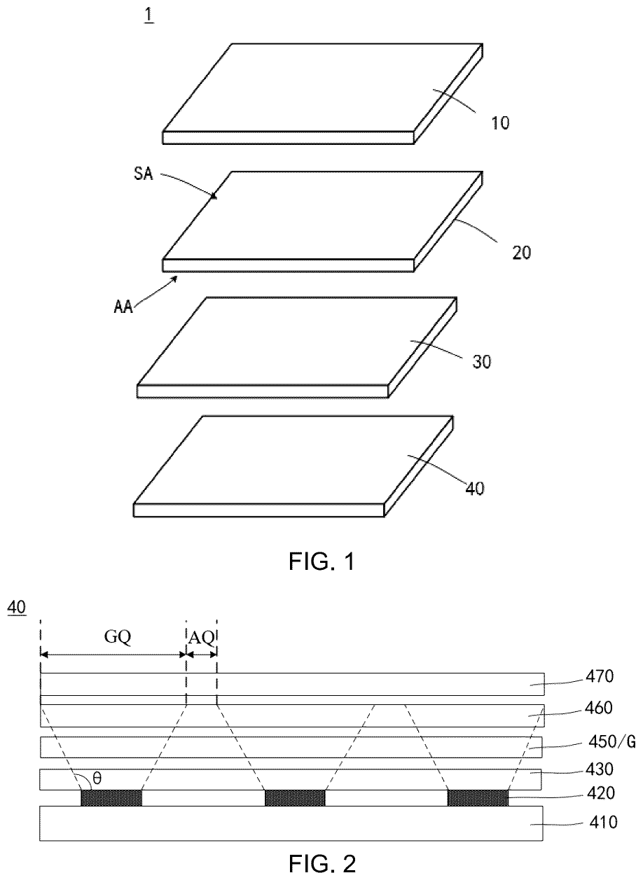

FIG. 1 is a structural diagram of a display apparatus, in accordance with some embodiments.

Referring to FIG. 1, the display apparatus 1 includes a display panel 20. The display panel 20 has a display surface SA and a non-display surface AA that are opposite to each other. The display surface SA is a surface of the display panel that is capable of displaying images, and the non-display surface AA is a surface opposite to the display surface AA.

The display panel 20 is configured to receive a data signal (e.g., a voltage signal) and display an image (i.e., a picture) on the display surface SA based on the data signal.

For example, the display panel 20 includes a plurality of sub-pixels located in a display area AA. The plurality of sub-pixels include first sub-pixels for emitting light of a first color, second sub-pixels for emitting light of a second color, and third sub-pixels for emitting light of a third color. The first color, second color, and third color are three primary colors (e.g., red, green, and blue). For example, the display panel may include red sub-pixels, green sub-pixels and blue sub-pixels.

The display panel 20 further includes a plurality of signal lines, such as a plurality of gate lines and a plurality of data lines. Each sub-pixel may be coupled to a gate line and a data line, and configured to write a data signal transmitted by the data line in response to a scanning signal transmitted by the gate line and emit light with a corresponding intensity based on the data signal.

The plurality of gate lines may extend substantially in a first direction. In some examples, a gate line may be parallel to the first direction. In some other examples, a relatively small included angle may exist between an extension direction of a gate line and the first direction. For example, the relatively small included angle is in a range from −8° to 8°, or −5° to 5°, inclusive. Hereinafter, the relatively small included angle described may refer to these value range of the included angle, and may be adaptively selected within this value range. A (e.g., each) gate line may be coupled to sub-pixels in a same row and configured to transmit a scanning signal to sub-pixels in the row. For example, the gate lines are located in the display area AA, and may also extend into a non-display area SA.

In some examples, the display panel 20 may further include a gate driving circuit located in the non-display area. In this case, the gate driving circuit may be referred to as a gate on array (GOA) circuit. The gate driving circuit is coupled to the plurality of data lines and configured to provide a scanning signal for the gate lines. For example, the gate driving circuit may be disposed on a side (e.g., left side or right side) of the display area in the first direction. In some other examples, the gate driving circuit may be a gate driver chip, which is not included in the display panel 20 but coupled to the plurality of gate lines in the display panel 20.

The plurality of data lines may extend substantially in a second direction. The second direction is perpendicular to the first direction. For example, a date line may be parallel to the second direction. In some examples, a relatively small included angle may exist between a date line and the second direction. A (e.g., each) data line may be coupled to sub-pixels in a same column and configured to provide a data signal for the sub-pixels in the column. For example, the data lines are located in the display area AA, and may also extend to the non-display area SA.

A display module may include a driver chip, which may specifically be a driver integrated circuit (IC), such as a source driver IC or a display driver integrated circuit (DDIC). The driver chip is coupled to the display panel 20 and maybe bonded to, for example, the non-display area SA of the display panel 20. The driver chip is configured to provide a corresponding data signal for the display panel 20 based on the received image data. In some examples, the driver chip is coupled to the plurality of data lines and configured to provide data signals for the data lines.

For convenience of description, a rectangular coordinate system may be created by using the first direction and the second direction as two axes perpendicular to each other.

In some embodiments, the display apparatus 1 further includes a light-emitting module 40. The light-emitting module 40 is a product capable of emitting light or a component of a light-emitting product. In some possible implementations, the light-emitting module 40 may be used for lighting; for example, the light-emitting module 40 may be a light panel or a backlight module. In some other possible implementations, the light-emitting module 40 may be used to display images; for example, the light-emitting module 40 may be a decorative wall or traffic lights.

For example, in a case where the display panel 20 is a liquid crystal display panel, the corresponding display module is a liquid crystal display module. Since the liquid crystal display panel 20 cannot emit light by itself, the light-emitting module 40 is disposed on the non-display surface AA of the display panel 20 and configured to provide backlight for the liquid crystal display panel 20. In this case, the light-emitting module 40 may be referred to as a backlight module. That is, a display apparatus including the backlight module and the liquid crystal display module may be referred to as a liquid crystal display apparatus. In a case where the display panel 20 is a liquid crystal display panel, the liquid crystal display apparatus 1 further includes a first polarizer 10 (also referred to as an upper polarizer) that is attached to the display surface SA of the liquid crystal display panel, and a second polarizer 30 (also referred to as a lower polarizer) that is attached to the non-display surface AA of the liquid crystal display panel 20. The polarization direction of the first polarizer 10 is perpendicular to the polarization direction of the second polarizer 30.

Embodiments of the present disclosure provide a light-emitting module. The light-emitting module 40 may include a substrate 410, an optical film G, and a plurality of light-emitting devices 420.

The substrate 410 may be provided according to actual needs.

For example, the substrate 410 may be a rigid substrate. A material of the rigid substrate may be glass, polymethyl methacrylate (PMMA), or the like. Alternatively, the substrate 410 may be a flexible substrate. A material of the flexible substrate may be polyethylene terephthalate (PET), polyethylene naphthalate (PEN), ultra-thin glass or polyimide (PI), etc. In a case where the substrate 410 is a flexible substrate, the light-emitting module 40 may be a flexible light-emitting module 40 and applied to a curved display apparatus.

The light-emitting device 420 is a device that can emit light after being energized. For example, the light-emitting device 420 may be an LED, a tiny-sized LED, a quantum dot light-emitting diode (QLED) or the like, which is not limited here. As an example, the light-emitting device 420 may be a micro light-emitting device, and a size of the micro light-emitting device may refer to a size of the tiny-sized LED. The tiny-sized LED includes submillimeter or even micron-sized light-emitting diode, and may also include a light-emitting diode with an even smaller size. The submillimeter light-emitting diode is also referred to as a mini LED; a size (e.g., length) of a mini LED may be in a range from 50 microns to 150 microns, such as from 80 microns to 120 microns, or may be 100 microns or below. The micron-sized light-emitting diode is also referred to as a micro light-emitting diode (micro LED); for example, a size (e.g., length) of a micro LED may be less than 50 microns, such as in a range of 10 microns to 50 microns.

The plurality of light-emitting devices are disposed on the substrate 410. For example, as shown in FIG. 2, the plurality of light-emitting devices 420 are disposed on an upper surface of the substrate 410. The plurality of light-emitting devices 420 are configured to emit light toward a side away from the substrate 410. For example, the plurality of light-emitting devices 420 are configured to emit light toward the non-display surface AA of the display panel 20 shown in FIG. 1.

The optical film G is disposed on a side of the plurality of light-emitting devices 420 away from the substrate 410, so that the luminance of the light-emitting device 420 becomes more uniform after the light emitted by the light-emitting device 420 passes through the optical film G.

For example, the light-emitting module 40 may further include a quantum dot film 430, a diffusion film 450, a light-homogenizing film 460 and a brightness enhancement film 470 that are stacked in sequence on a side of the light-emitting device 420 away from the substrate 410. In some examples, the number of the quantum dot film 430, the diffusion film 450, the light-homogenizing film 460 and the brightness enhancement film 470 may all be one, which is conducive to the development of the light-emitting module 40 in the direction of being thin and light. In some examples, the number of the quantum dot film 430, the diffusion film 450, the light-homogenizing film 460 and the brightness enhancement film 470 may all be multiple.

In some examples, the optical film G may be the diffusion film 450 shown in FIG. 2. In some other examples, the optical film G may be a light-homogenizing film 460.

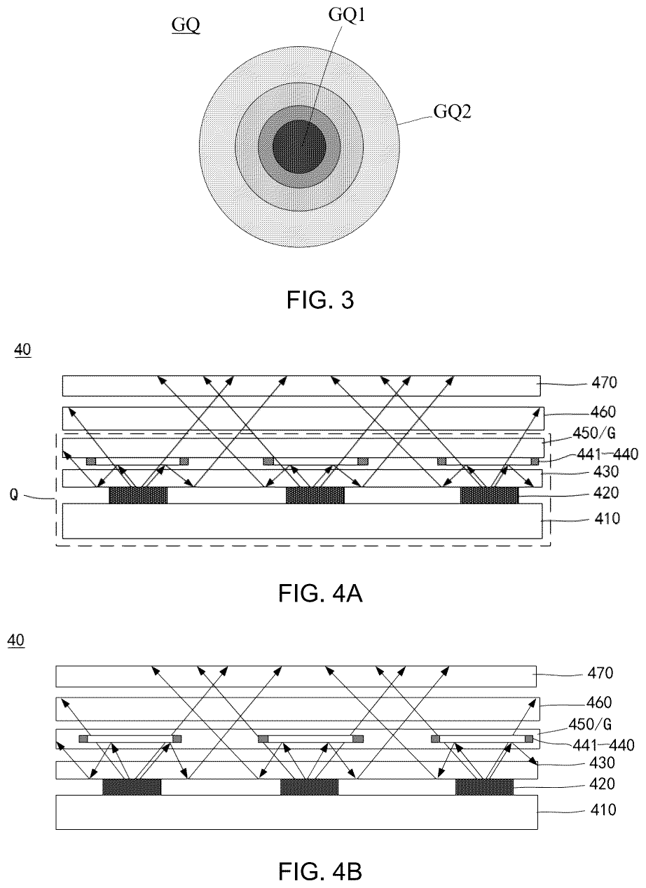

The light emitted by the light-emitting device 420 propagates toward the side away from the substrate 410 to the optical film G, and passes through the optical film G and continues to propagate toward the side away from the substrate 410, so that the light-emitting module 40 emits light. With continued reference to FIG. 2, the light-emitting module 40 has a plurality of light projection regions GQ. The light projection region GQ is a region in a plane where the reflective structure 440 mentioned below is located and illuminated by the light emitted by a light-emitting device 420; it can be understood that, a light projection region may be a region on the optical film G or the brightness enhancement film 470 that is illuminated by the light emitted by a light-emitting device 420. In some examples, referring to FIG. 3, in a direction from a geometric center region GQ1 of the light projection region GQ to an outer edge GQ2 of the light projection region GQ, the luminous intensity in the light projection region GQ is gradually reduced. For example, the luminous intensity of the light projection region GQ at the outer edge GQ2 is zero. The geometric center region GQ1 may be understood as a region in the light projection region GQ on the optical film G or the brightness enhancement film 470 that is illuminated by the light with the greatest luminous intensity of the light-emitting device 420. In some examples, the light projection region GQ may have a regular shape. For example, the regular shape may be an ellipse, or a rectangle, which is not limited here.

However, a dark projection region AQ exists between adjacent light projection regions GQ. Due to the difference in luminance of the light projection region GQ and the dark projection region AQ, the light emitted by the light-emitting module is unevenly luminous. As a result, light shadows appear on the image displayed by the liquid crystal display panel, which affects the image effect.

In order to solve the problem of uneven luminance of the light emitted by the light-emitting module 40, referring to FIG. 4A, the light-emitting module 40 further includes a reflective structure 440. The reflective structure 440 is configured to reflect the light emitted by the light-emitting devices 420. In some examples, the reflective structure 440 is further configured to transmit the light emitted by the light-emitting devices 420.

The reflective structure 440 is disposed on the optical film G. In some examples, as shown in FIG. 4A, the reflective structure 440 is disposed on a side of the optical film G proximate to the substrate 410; for example, the reflective structure 440 is disposed on a side of the diffusion film 450 proximate to the substrate 410. In some other examples, the reflective structure 440 is disposed on a side of the optical film G away from the substrate 410. In some other examples, as shown in FIG. 4B, the reflective structure 440 is disposed inside the optical film G. For example, as shown in FIG. 4B, the reflective structure 440 may be disposed inside the diffusion film 450, so that light transmittance of a portion of the diffusion film 450 in which the reflective structure 440 is disposed is less than light transmittance of a portion of the diffusion film 450 in which no reflective structure 440 is disposed; that is, unit illumination intensity of the portion of the diffusion film 450 in which the reflective structure 440 is disposed is less than unit illumination intensity of the portion of the diffusion film 450 in which no reflective structure 440 is disposed. In this way, compared with the portion of the diffusion film 450 in which no reflective structure 440 is disposed, the diffusion effect of the portion of the diffusion film 450 in which the reflective structure 440 is disposed is weakened. As a result, the thickness of the light-emitting module 40 can be reduced.

In this way, part of the light emitted by the light-emitting device 420 is reflected by the reflective structure 440 and propagates toward the substrate 410, and then is reflected by the substrate 410 and propagates toward the light projection region GQ and the dark projection region AQ shown in FIG. 2, which increases the luminance of the dark projection region AQ shown in FIG. 2. In addition, another part of the light emitted by the light-emitting device 420 is transmitted to the light projection region GQ through the reflective structure 440. Therefore, the luminance of the light emitted by the light-emitting module 40 is substantially consistent, thereby alleviating the problem of uneven luminance of the light output by the light-emitting module 40.

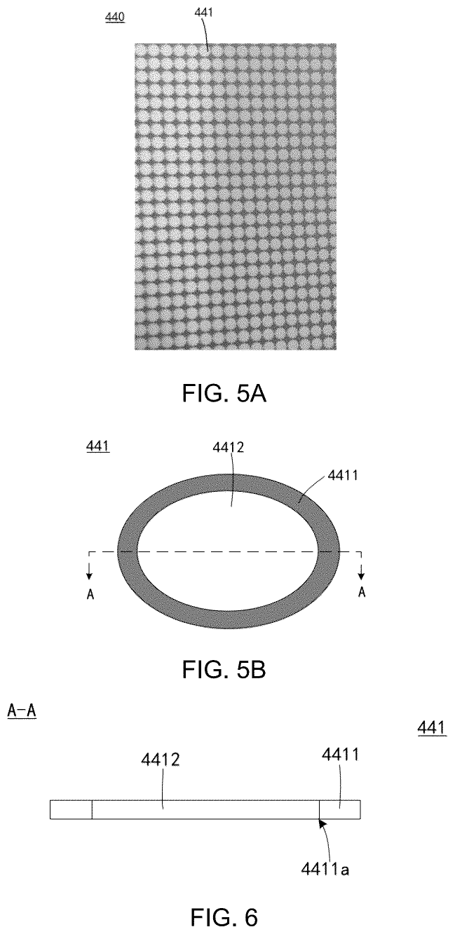

FIG. 5A is a structural diagram of the reflective structure 440, in accordance with some embodiments. The reflective unit 441 shown in FIG. 5A is the reflective unit 441 described in Example 2 below. The reflective unit 441 shown in FIG. 5A is not limited to the reflective unit 441 described in Example 2 below; for example, the reflective unit 441 shown in FIG. 5A may be replaced with the reflective unit 441 described in Example 1 below, which will not be repeated. FIG. 5B is a structural diagram of a reflective unit 441, in accordance with some embodiments. The reflective unit 441 shown in FIG. 5B is the reflective unit 441 described in Example 1 below. It will be understood that the reflective unit 441 shown in FIG. 5B is not limited to the reflective unit 441 described in Example 1 below; for example, the reflective unit 441 shown in FIG. 5B may be replaced with the reflective unit 441 described in Example 2 below, which will not be repeated.

Referring to FIG. 5A, the reflective structure 440 includes a plurality of reflective units 441. In some examples, the plurality of reflective units 441 are connected to each other. For example, a row of reflective units 441 are connected, and a column of reflective units 441 are connected. A row of reflective units 441 may be multiple reflective units 441 arranged in the first direction, and a column of reflective units 441 may be multiple reflective units 441 arranged in the second direction.

Referring to FIG. 5B, each reflective unit 441 includes a first reflective pattern 4411 and at least one (e.g., one or more) second reflective pattern 4412. The first reflective pattern 4411 and the second reflective pattern 4412 are both configured to reflect the light emitted by the light-emitting device 420 to form reflected light, and the reflected light is reflected by the substrate 410 onto the optical film G.

Referring to FIG. 5B, at least a portion of the first reflective pattern 4411 is arranged surrounding at least one (e.g., one or more) second reflective pattern 4412.

For example, the first reflective pattern 4411 is arranged surrounding at least one (e.g., one or more) second reflective pattern 4412. In some examples, referring to FIG. 6, the first reflective pattern 4411 is arranged surrounding one second reflective pattern 4412. In some other examples, the first reflective pattern 4411 is arranged surrounding a plurality of (e.g., four) second reflective patterns 4412.

Referring to FIG. 6, the first reflective pattern 4411 has at least one (e.g., one or more) hollow region 4411a, and the second reflective pattern 4412 is disposed in the hollow region 4411a. In this way, the first reflective pattern 4411 and the second reflective pattern 4412 are disposed in a same layer, so that the thickness of the reflective unit 441 is relatively small, which avoids increasing the thickness of the light-emitting module 40 to facilitate the development of the products such as display panel 20 towards thinness and lightness. In a reflective unit 441, the number of the hollow region 4411a is equal to the number of the second reflective pattern 4412; for example, the number of the hollow region 4411a and the number of the second reflective pattern 4412 may both be one, four, six, or nine. In some examples, with continued reference to FIG. 6, a first reflective pattern 4411 has one hollow region 4411a, and a second reflective pattern 4412 is disposed in the hollow region 4411a. In some other examples, a first reflective pattern 4411 has a plurality of (e.g., four) hollow regions 4411a, and a plurality of (e.g., four) second reflective patterns 4412 are disposed in the plurality of (e.g., four) hollow regions 4411a.

In a possible implementation, the hollow region 4411a and the second reflective pattern 4412 have a same shape, which may be understood as that an outline of the hollow region 4411a and an outline of the second reflective pattern 4412 have a same shape. For example, in a case where the shape of the hollow region 4411a is an ellipse, correspondingly, the shape of the second reflective pattern 4412 is also an ellipse. In this embodiment, the shapes of the hollow region 4411a and the second reflective pattern 4412 are not limited.

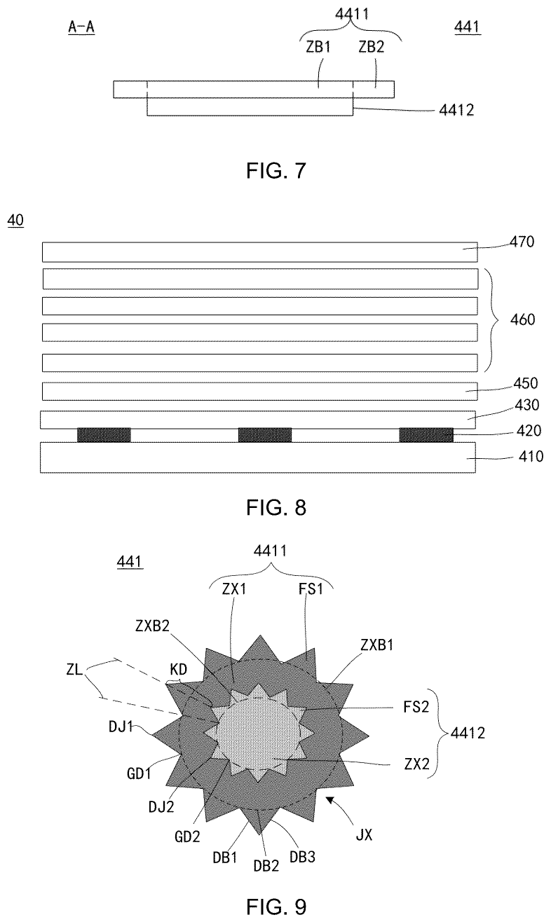

As another example, referring to FIG. 7, a first reflective pattern 4411 and a second reflective pattern 4412 are stacked. The second reflective pattern 4412 is closer to the substrate 410 shown in FIG. 4A than the first reflective pattern 4411. A portion of the first reflective pattern 4411 is arranged surrounding at least one (e.g., one or more) second reflective pattern 4412, and an orthographic projection of another portion of the first reflective pattern 4411 on the substrate coincides with an orthographic projection of at least one (e.g., one or more) second reflective pattern 4412 on the substrate. In some examples, the first reflective pattern 4411 includes a first sub-portion ZB1 and a second sub-portion ZB2. An orthographic projection of the first sub-portion ZB1 on the substrate 410 coincides with an orthographic projection of the second reflective pattern 4412 on the substrate; the second sub-portion ZB2 is located outside the second reflective pattern 4412 and arranged surrounding the first sub-portion ZB1.

With continued reference to FIG. 4A, the orthographic projection of the second reflective pattern 4412 on the substrate 410 overlaps with an orthographic projection of a light-emitting device 420 on the substrate 410, which allows the light with a relatively great luminous intensity emitted by the light-emitting device to illuminate the second reflective pattern 4412 to form reflected light (recorded as first reflected light), and allows the light with a relatively small luminous intensity emitted by the light-emitting device to illuminate the first reflective pattern 4411 to form reflected light (recorded as second reflected light).

A reflectivity of the first reflective pattern 4411 is less than a reflectivity of the second reflective pattern 4412, so that the second reflective pattern 4412 reflects more light that is emitted by the light-emitting device 420, and the first reflective pattern reflects less light that is emitted by the light-emitting device 420. In this way, the first reflected light with greater luminous intensity and larger quantity may be formed on the second reflective pattern 4412, and the second reflected light with less luminous intensity and less quantity may be formed on the first reflective pattern 4411. The first reflected light and the second reflected light may propagate to the light projection region GQ and the dark projection region AQ shown in FIG. 2, which increases the luminance of the dark projection region AQ shown in FIG. 2. Compared with a situation where the reflectivity of the reflective structure is the same everywhere, in the embodiments of the present disclosure, the luminance uniformity of the dark projection region AQ and the light projection region GQ shown in FIG. 2 is better.

The reflectivity of the first reflective pattern 4411 is equal to the reflectivity of the second reflective pattern 4412, so that the first reflected light with greater luminous intensity may be formed on the second reflective pattern 4412, and the second reflected light with less luminous intensity may be formed on the first reflective pattern 4411. Thus, the first reflected light and the second reflected light may propagate to the light projection region GQ and the dark projection region AQ shown in FIG. 2, which increases the luminance of the dark projection region AQ shown in FIG. 2. Compared with a situation where the reflectivity of the reflective structure is the same everywhere, in the embodiments of the present disclosure, the luminance uniformity of the dark projection region AQ and the light projection region GQ shown in FIG. 2 is better.

Embodiments of the present disclosure provide a comparative solution. Referring to FIG. 8. In the light-emitting module 40 provided by this comparative solution, the number of light-homogenizing films 460 is increased, and the number of light-homogenizing films 460 is in a range of 3 to 5 (e.g., the number of the light-homogenizing films 460 shown in FIG. 8 is four) in general, so as to alleviate the problem of uneven luminance of light emitted by the light-emitting module 40. On the other hand, in the embodiments of the present disclosure, a reflective structure 440 is provided on the optical film G to alleviate the problem of uneven luminance of light emitted by the light-emitting module 40. In this way, even for the case that the number of light-emitting devices 420 in the light-emitting module is reduced (i.e., a distance between adjacent light-emitting devices 420 is increased), the dimension of the dark projection region AQ is increased, and thus the light shadow problem of the display panel becomes more serious, the light-emitting module 40 in embodiments of the present disclosure uses the reflective structure 440 to reflect the light emitted by the light-emitting devices 420 to the dark projection region AQ as shown in FIG. 2, so that the luminance uniformity of the light output by the light-emitting module 40 is good, and the problem of more serious light shadows on the display panel 20 is alleviated. Meanwhile, the number of layers of the light-homogenizing film 460 is not increased (i.e., the number of the light-homogenizing film 460 is one), so that the thickness of the light-emitting module 40 is not increased, which is conducive to the development of the light-emitting module 40 towards thinness and lightness and the low manufacturing cost.

In some examples, an orthographic projection of a light-emitting device 420 on the substrate 410 covers an orthographic projection of a second reflective pattern 4412 on the substrate 410. For example, an orthographic projection of a light-emitting device 420 on the substrate 410 partially overlaps with an orthographic projection of a first reflective pattern 4411 on the substrate 410. In some other examples, an orthographic projection of a second reflective pattern 4412 on the substrate 410 partially overlaps with an orthographic projection of a light-emitting device 420 on the substrate 410.

A material of the reflective structure 440 may be a material capable of transmitting and reflecting, which may be referred to as a light-transmitting material. The light-transmitting material may be, for example, ink, optical resin, or latex paint. In order to make the reflectivity of the first reflective pattern 4411 less than or equal to the reflectivity of the second reflective pattern 4412, several examples are provided below.

For example, the first reflective pattern 4411 is made of a first ink, and the second reflective pattern 4412 is made of a second ink. For example, a reflectivity of the first ink is less than a reflectivity of the second ink; the second ink may be white ink, or gray ink, and the first ink may be black ink. As another example, the reflectivity of the first ink is equal to the reflectivity of the second ink.

As another example, a density of the first reflective pattern 4411 is less than or equal to a density of the second reflective pattern 4412, which may be understood as that, the first reflective pattern 4411 and the second reflective pattern 4412 are formed by coating with a light-transmitting material, and a coating density of the first reflective pattern 4411 is less than or equal to a coating density of the second reflective pattern 4412. In some examples, the reflectivity of the first ink is equal to the reflectivity of the second ink, and the density of the first reflective pattern 4411 is less than or equal to the density of the second reflective pattern 4412. In some other examples, the reflectivity of the first ink is less than the reflectivity of the second ink, and the density of the first reflective pattern 4411 is less than or equal to the density of the second reflective pattern 4412.

As another example, a thickness of the first reflective pattern 4411 is less than the thickness of the second reflective pattern 4412, which may be understood as that, in a thickness direction of the light-emitting module, a dimension of the first reflective pattern 4411 is less than a dimension of the second reflective pattern 4412. In some examples, the reflectivity of the first ink is equal to the reflectivity of the second ink, and the thickness of the first reflective pattern 4411 is less than or equal to the thickness of the second reflective pattern 4412. In some other examples, the reflectivity of the first ink is less than the reflectivity of the second ink, and the thickness of the first reflective pattern 4411 is less than or equal to the thickness of the second reflective pattern 4412.

In a possible implementation, the first reflective pattern 4411 and the second reflective pattern 4412 may be the same ink; the density of the first reflective pattern 4411 is less than the density of the second reflective pattern 4412. The thickness of the first reflective pattern 4411 is less than the thickness of the second reflective pattern 4412.

In another possible implementation, the first reflective pattern 4411 is made of a first ink, the second reflective pattern 4412 is made of a second ink, and the reflectivity of the first ink is less than the reflectivity of the second ink; the density of the first reflective pattern 4411 is less than the density of the second reflective pattern 4412; the thickness of the first reflective pattern 4411 is less than the thickness of the second reflective pattern 4412.

In some embodiments, both an outer edge of the first reflective pattern 4411 and the second reflective pattern 4412 may have a regular shape. The outer edge of the first reflective pattern 4411 is an edge of the first reflective pattern 4411 away from the second reflective pattern 4412. Three examples of the first reflective pattern 4411 and the second reflective pattern 4412 are described below.

### Example 1

With continued reference to FIG. 5B, the outer edge of the first reflective pattern 4411 has a regular shape such as an ellipse or a circle. The second reflective pattern 4412 is in a shape of an ellipse or a circle.

In some examples, the first sub-portion ZB1 shown in FIG. 7 or the hollow region 4411a shown in FIG. 6 is in a shape of an ellipse, and correspondingly, the second reflective pattern 4412 is in a shape of an ellipse. In some other examples, the first sub-portion ZB1 shown in FIG. 7 or the hollow region 4411a shown in FIG. 6 is in a shape of a circle, and correspondingly, the second reflective pattern 4412 is in a shape of a circle.

### Example 2

Referring to FIG. 9, the first reflective pattern 4411 includes a first central portion ZX1 and a plurality of first radiating portions FS1. The first central portion ZX1 is arranged surrounding the second reflective pattern 4412, and the plurality of first radiating portions FS1 are circumferentially arranged around the first central portion ZX1 such that a gap JX exists between adjacent first radiating portions FS1, i.e., no reflective structure 440 exists between adjacent first radiating portions FS1. In this way, the light with a same luminous intensity emitted by the light-emitting device 420 may illuminate the first radiation portions FS1 and may also pass through the gap JX between adjacent first radiation portions FS1.

In some examples, in a case where the first reflective pattern 4411 has a hollow region 4411a shown in FIG. 6, a portion of the first reflective pattern 4411 excluding the hollow region 4411a may include a first central portion ZX1 and a plurality of first radiating portions FS1. In some examples, in a case where the first reflective pattern 4411 includes a first sub-portion ZB1 and a second sub-portion ZB2 shown in FIG. 7, the second sub-portion ZB2 may include a first central portion ZX1 and a plurality of first radiating portions FS1.

In some examples, the first central portion ZX1 may have a regular shape. For example, an outer edge ZXB1 of the first central portion ZX1 may be in a shape of a polygon (e.g., a rectangle), a circle, or an ellipse. In a possible implementation, in a case where the outer edge ZXB1 of the first central portion ZX1 is in a shape of a circle, the plurality of first radiating portions FS1 are arranged in a circular array around the center of the first central portion ZX1 and at the outer edge of the first central portion ZX1.

In some examples, the number of the plurality of first radiating portions FS1 is greater than or equal to five; in this way, for the light emitted by the light-emitting device 420, the light passing through the gap between adjacent first radiating portions FS1 is relatively less, and the light reflected by the first radiating portions FS1 is relatively more. For example, the number of the plurality of first radiating portions FS1 may be five, six, seven, eight, ten, or twelve.

In some examples, a reflectivity of the first central portion ZX1 is equal to a reflectivity of the first radiating portion FS1. In a possible implementation, a material of the first central portion ZX1 and a material of the first radiating portion FS1 are the same, which facilitates production and reduces the process steps. In another possible implementation, the materials of the first central portion ZX1 and the first radiating portion FS1 are different, but reflectivities of the two are the same. A transmittance of the first central portion ZX1 and a transmittance of the first radiating portion FS1 may be the same.

In some other examples, the reflectivity of the first central portion ZX1 is greater than the reflectivity of the first radiating portion FS1, so that the first central portion ZX1 reflects more light emitted by the light-emitting device 420, and the first radiating portion FS1 reflects less light emitted by the light-emitting device 420. According to a distribution of luminous intensity in the light projection region GQ shown in FIG. 3, the light emitted by the light-emitting device 420 illuminates the first central portion ZX1 with a relatively great luminous intensity and illuminates the first radiating portion FS1 with a relatively small luminous intensity.

In this way, reflected light with greater luminous intensity and larger quantity may be formed on the first central portion ZX1, and reflected light with less luminous intensity and smaller quantity may be formed on the first radiating portion FS1. The reflected light propagates to the light projection region GQ and the dark projection region AQ shown in FIG. 2, which increases the luminance of the dark projection region AQ shown in FIG. 2, so that the luminance uniformity of the dark projection region AQ and the light projection region GQ shown in FIG. 2 is good. As a result, the light emitted by the light-emitting module is uniform.

In a possible implementation, the material of the first central portion ZX1 and the material of the first radiating portion FS1 are different, and the transmittance of the first central portion ZX1 may be less than the transmittance of the first radiating portion FS1.

The second reflective pattern 4412 includes a second central portion FS2 and a plurality of second radiating portions ZX2, and the plurality of second radiating portions ZX2 are circumferentially arranged around the second central portion FS2. In some examples, in a case where the first reflective pattern 4411 includes a first sub-portion ZB1 and a second sub-portion ZB2 shown in FIG. 7, the first sub-portion ZB1 may include a second central portion FS2 and a plurality of second radiating portions ZX2.

In some examples, the second central portion FS2 may have a regular shape, and the regular shape may be a polygon (e.g., a rectangle), a circle, an ellipse, or other regular shapes. For example, in a case where the second central portion FS2 is in a shape of a circle, the plurality of second radiating portions ZX2 are arranged in a circular array around the center of the second central portion FS2 and at an outer edge of the second central portion FS2.

In some examples, a reflectivity of the second central portion FS2 is equal to a reflectivity of the second radiating portion ZX2. In a possible implementation, a material of the second central portion FS2 and a material of the second radiating portion ZX2 are the same, which facilitates production and reduces process steps. In another possible implementation, the materials of the second central portion FS2 and the second radiating portion ZX2 are different, but the reflectivities of the two are the same. A transmittance of the second central portion FS2 and a transmittance of the second radiating portion ZX2 may be the same.

In some other examples, the reflectivity of the second central portion FS2 is greater than the reflectivity of the second radiating portion ZX2, so that the first central portion ZX1 reflects more light emitted by the light-emitting device 420, and the first radiating portion FS1 reflects less light emitted by the light-emitting device 420. According to the distribution of luminous intensity in the light projection region GQ shown in FIG. 3, the light emitted by the light-emitting device 420 illuminates the second central portion FS2 with a relatively great luminous intensity and illuminates the second radiating portion ZX2 with a relatively small luminous intensity.

In this way, reflected light with greater luminous intensity and larger quantity may be formed on the second central portion FS2, and reflected light with less luminous intensity and smaller quantity may be formed on the second radiating portion ZX2. The reflected light propagates to the light projection region GQ and the dark projection region AQ shown in FIG. 2, which increases the luminance of the dark projection region AQ shown in FIG. 2, so that the luminance uniformity of the dark projection region AQ and the light projection region GQ shown in FIG. 2 is good. As a result, the light emitted by the light-emitting module is uniform.

In a possible implementation, the material of the second central portion FS2 and the material of the second radiating portion ZX2 are different. The transmittance of the second central portion FS2 may be less than the transmittance of the second radiating portion ZX2.

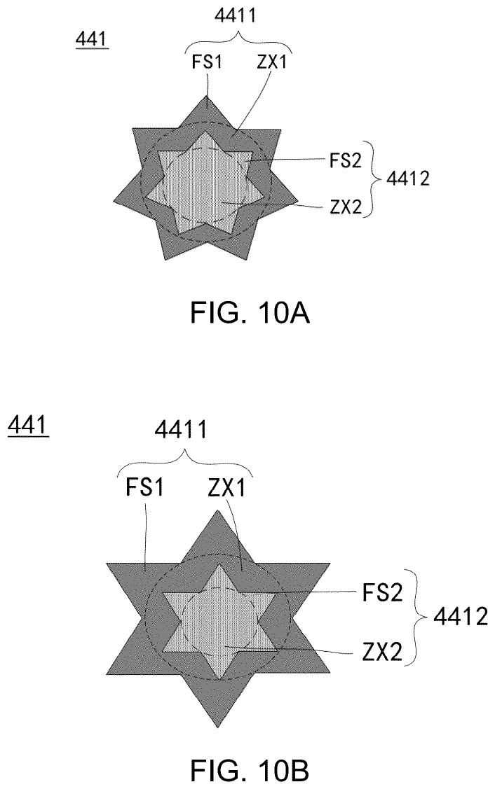

In some examples, the number of the plurality of first radiating portions FS1 and the number of the plurality of second radiating portions ZX2 are equal. The numbers of the plurality of first radiating portions FS1 and the plurality of second radiating portions ZX2 may both be four, six, seven, nine, twelve, or sixteen. For example, as shown in FIG. 9, the numbers of the first radiating portion FS1 and the second radiating portion ZX2 are both twelve; as shown in FIG. 10A, the numbers of the first radiating portion FS1 and the second radiating portion ZX2 are both seven; as shown in FIG. 10B, the numbers of the first radiating portion FS1 and the second radiating portion ZX2 are both six. In some examples, the plurality of first radiating portions FS1 are symmetrically distributed. For example, as shown in FIG. 9, the plurality of first radiating portions FS1 are distributed in a bilateral symmetry manner. In some examples, the plurality of second radiating portions ZX2 are symmetrically distributed. For example, as shown in FIG. 9, the plurality of second radiating portions ZX2 are distributed in a bilateral symmetry manner.

In some embodiments, extension directions of the first radiating portions FS1 are the same as extension directions of the respective second radiating portions ZX2, which may be understood as that a connection line passing through an extension direction of a first radiating portion FS1 and an extension direction of a corresponding second radiating portion ZX2 is a straight line ZX; for example, a connection line passing through an end of a first radiating portion FS1 and an end of a second radiating portion ZX2 is a straight line ZX, and the straight line also passes through the center of the reflective unit shown in FIG. 9, FIG. 10A and FIG. 10B.

In this way, in any at least two directions (e.g. the first direction and the second direction below) parallel to a plane where the first reflective pattern 4411 is located, widths KD of the first reflective pattern 4411 are equal, so that the second reflective pattern may reflect light onto the first reflective pattern, and thus the first reflective pattern may reflect more light. The width KD of the first reflective pattern 4411 may be understood as a dimension of the first reflective pattern 4411 in this direction (e.g., the first direction or the second direction below).

In some examples, a first radiating portion FS1 may have a first tip DJ1 and a first trough GD1. The first trough GD1 is closer to the second reflective pattern 4412 than the first tip DJ1. The second radiating portion ZX2 has a second tip DJ2 and a second trough GD2. The second tip DJ2 is closer to the first reflective pattern 4411 than the second trough GD2. Extension directions of the first radiating portions FS1 coincide with extension directions of the respective second radiating portions ZX2, which may be understood as that a connection line passing through the first tip DJ1 and the second tip DJ2 is a straight line ZX, and a connection line passing through the first trough GD1 and the second trough DG1 is a straight line ZL; that is, an extension direction of the first tip DJ1 and an extension direction of the second tip DJ2 are the same, and an extension direction of the first trough GD1 and an extension direction of the second trough DG1 are the same.

In some examples, a first radiating portion FS1 may have a root portion and an end portion, the root portion is disposed at the outer edge ZXB1 of the first central portion ZX1, and the end portion is disposed opposite to the root portion.

In a possible implementation, with continued reference to FIG. 9, the first radiating portion FS1 includes a first border DB1, a second border DB2 and a third border DB3 that are connected in sequence. The second border DB2 may be the root portion, and a corner (i.e., a connection portion between the first border DB1 and the third border DB3) corresponding to the second border DB2 may be the end portion. The connection portion between the first border DB1 and the third border DB3 may be curved, which may be understood as a rounded corner. The second border DB2 may be a curved border.

The first tip JD1 and the end of the first radiating portion FS1 may both be understood as the connection portion between the first border DB1 and the second border DB2, and the first trough GD1 may be understood as a connection portion between a first border DB1 of a first radiating portion FS1 and a third border DB3 of an adjacent first radiating portion FS1.

### Example 3

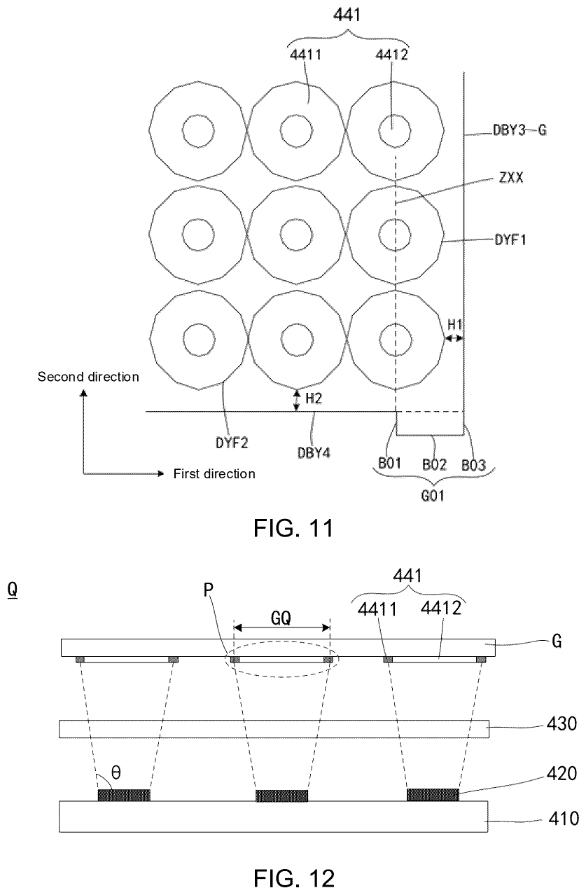

Referring to FIG. 11, an outer edge of the first reflective pattern 4411 has a regular shape such as a regular polygon, and the second reflective pattern 4412 has a regular shape such as a regular polygon.

In some examples, the outer edge of the first reflective pattern 4411 is in a shape of a regular polygon, and the second reflective pattern 4412 is in a shape of a regular polygon. For example, the regular polygon may be a regular dodecagon shown in FIG. 11. In a possible implementation, a shape of the first sub-portion ZB1 shown in FIG. 7 or a shape of the hollow region 4411a shown in FIG. 6 is the same as the shape of the second reflective pattern 4412.

Referring to FIG. 11, a distance between adjacent reflective units 441 is less than a distance between an outermost reflective unit and an edge of the optical film G.

The optical film G may include a third edge DBY3 and a fourth edge DBY4 that are perpendicular to each other, and the third edge DBY3 is connected to the fourth edge DBY4. An extension direction of the fourth edge DBY4 is parallel to the first direction; an extension direction of the third edge DBY3 is parallel to the second direction. There may be two third edges DBY3 and two fourth edges DBY4, so that a rectangular or square optical film G may be formed.

For example, among reflective units 441 in a same row, a distance between adjacent reflective units 441 in the first direction is less than a distance H1 between a first outermost reflective unit DYF1 and the third edge DBY3 of the optical film G. The first outermost reflective unit DYF1 may be understood as a reflective unit 441 that is closest to the third edge DBY3 of the optical film G among the reflective units 441 in a same row.

As another example, among reflective units 441 in a same column, a distance between adjacent reflective units 441 is less than a distance H2 between a second outermost reflective unit DYF2 and the fourth edge DBY4 of the optical film G in the second direction. The second outermost reflective unit DYF2 may be understood as a reflective unit 441 that is closest to the fourth edge DBY4 of the optical film G among the reflective units 441 in a same column.

With continued reference to FIG. 11, the optical film G has a protruding mounting portion G01, and the mounting portion G01 is configured to fix the optical film G. For example, the mounting portion G01 of the optical film G may be fixedly connected to a plastic frame or a middle frame, thereby fixing the optical film G to the plastic frame or the middle frame.

In some examples, the mounting portion G01 may have a regular shape such as a rectangle or a square, which facilitates a fabrication of the mounting portion G01 in the optical film G.

In some possible solutions, the mounting portion G01 includes a fifth edge B01, a sixth edge B02, and a seventh edge B03. The fifth edge B01 is connected to the sixth edge B02, the sixth edge B02 is connected to the seventh edge B03, and the fifth edge B01 is connected to the fourth edge DBY4. The seventh edge B03 may be connected to the fourth edge DBY4 or the third edge DBY3. For example, the fifth edge B01 is parallel to the third edge DBY3. As another example, the sixth edge B02 is parallel to the fourth edge DBY4, and the seventh edge B03 is parallel to the third edge DBY3.

In a case where the fifth edge B01 is parallel to the third edge DBY3, in the second direction, among first outmost reflective units DYF1 in a same column, an extension direction of a center line ZXX of each first outermost reflective unit DYF1 coincides with an extension direction of the fifth edge B01.

In some embodiments, a second reflective pattern 4412 is located in a light projection region GQ. In some examples, the second reflective pattern 4412 covers the geometric center of the light projection region GQ; in this way, the light with the greatest luminous intensity emitted by the light-emitting device 420 may illuminate the second reflective pattern 4412. Thus, the second reflective pattern 4412 may reflect the light with the greatest luminous intensity, and the light may propagate to, for example, the dark projection region AQ shown in FIG. 2, so that the luminance of the dark projection region AQ in the related art is enhanced, which makes the luminance uniformity of the dark projection region AQ and the light projection region GQ in the related art better.

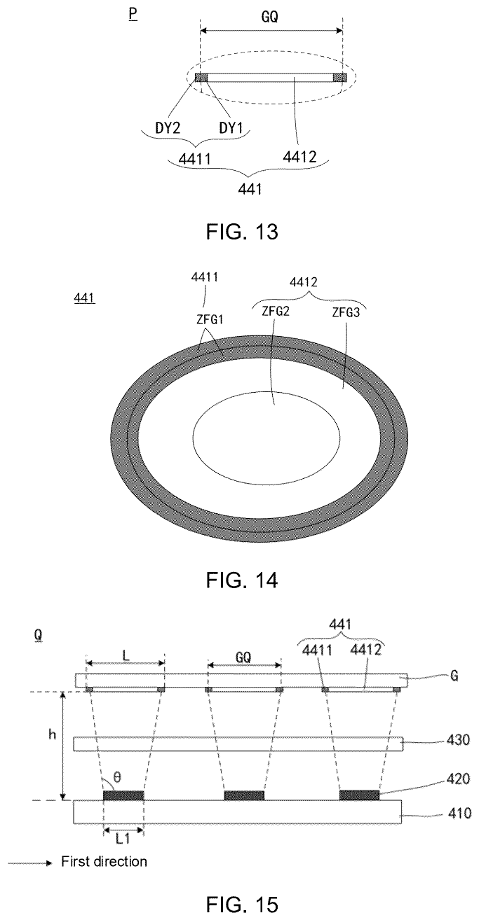

Referring to FIGS. 12 and 13, at least a portion of a first reflective pattern 4411 is located in a light projection region GQ. In some examples, the first reflective pattern 4411 is located in the light projection region GQ.

In some other examples, with continued reference to FIGS. 12 and 13, a portion of a first reflective pattern 4411 is located in a light projection region GQ, and another portion of the first reflective pattern 4411 is located outside the light projection region GQ. For example, in a reflective unit 441, the first reflective pattern 4411 includes a second portion DY2 and at least one (e.g., one or more) first portion DY1. The at least one first portion DY1 is located in the light projection region GQ, and the at least one first portion DY1 is arranged surrounding the second reflective pattern 4412. The second portion DY2 is located outside the light projection region GQ and is connected to the at least one first portion DY1. A portion of the first reflective pattern 4411 may be understood as the at least one first portion DY1, and the another portion of the first reflective pattern 4411 may be understood as the second portion DY2.

In a possible implementation, in a case where a reflective unit 441 includes one second reflective pattern 4412, in the reflective unit 441, the first reflective pattern 4411 includes a second portion DY2 and one first portion DY1. The first portion DY1 is located in the light projection region GQ, and the first portion DY2 is arranged surrounding the second reflective pattern 4412. The second portion DY2 is located outside the light projection region GQ and is connected to the first portion DY1.

In another possible implementation, in a case where a reflective unit 441 includes a plurality of second reflective patterns 4412, in the reflective unit 441, the first reflective pattern 4411 includes a second portion DY2 and a plurality of first portions DY1. The plurality of first portions DY1 are located in the light projection region GQ, and each first portion DY1 is arranged surrounding a second reflective pattern 4412. The second portion DY2 is located outside the light projection region GQ and is connected to the plurality of first portions DY1.

In some embodiments, both the first reflective pattern 4411 and the second reflective pattern 4412 are capable of transmitting light. In this way, the light emitted by the light-emitting device 420 may not only pass through the first reflective pattern 4411 and the second reflective pattern 4412, but also be reflected by the first reflective pattern 4411 and the second reflective pattern 4412. In some examples, a transmittance of the second reflective pattern 4412 is less than a transmittance of the first reflective pattern 4411. According to the distribution of luminous intensity of the light emitted by the light-emitting device 420 shown in FIG. 3, the light emitted by the light-emitting device 420 illuminates the second reflective pattern 4412 with a relatively great luminous intensity and illuminates the first reflective pattern 4411 with a relatively small luminous intensity. In this way, the second reflective pattern 4412 may transmit less but reflect more light with a greater luminous intensity, and the first reflective pattern 4411 may transmit more but reflect less light with a less luminous intensity.

In some embodiments, referring to FIG. 14, the first reflective pattern 4411 includes a plurality of first reflective sub-patterns ZFG1, and the plurality of first reflective sub-patterns ZFG1 are sequentially arranged surrounding a second reflective pattern 4412. In a direction from the second reflective pattern 4412 to the first reflective pattern 4411, reflectivities of the plurality of first reflective sub-patterns ZFG1 decrease in sequence. The reflectivity of the second reflective pattern 4412 is greater than the reflectivities of the plurality of first reflective sub-patterns ZFG1.

In some examples, in a case where the first reflective pattern 4411 includes two first reflective sub-patterns ZFG1, the two first reflective sub-patterns ZFG1 may be the first central portion ZX1 and the first radiating portion FS1 shown in FIG. 9.

In some other embodiments, with continued reference to FIG. 14, a second reflective pattern 4412 includes a second reflective sub-pattern ZFG2 and at least one (e.g., one or more) third reflective sub-pattern ZFG3. The at least one third reflective sub-pattern ZFG3 is sequentially arranged surrounding the second reflective sub-pattern ZFG2. In a direction from the second reflective pattern 4412 to the first reflective pattern 4411, reflectivities of the second reflective sub-pattern ZFG2 and the at least one third reflective sub-pattern ZFG3 decrease in sequence. The reflectivity of the second reflective sub-pattern ZFG2 and the reflectivity of the third reflective sub-pattern ZFG3 are both greater than the reflectivity of the first reflective pattern 4411.

In some examples, in a case where the second reflective pattern 4412 includes a second reflective sub-pattern ZFG2 and a third reflective sub-pattern ZFG3, the second reflective sub-pattern ZFG2 may be the second central portion FS2 shown in FIG. 6, and the third reflective sub-pattern ZFG3 may be the plurality of second radiating portions ZX2 shown in FIG. 9.

In some other embodiments, in the direction from the second reflective pattern 4412 to the first reflective pattern 4411, reflectivities of the second reflective sub-pattern ZFG2, the at least one third reflective sub-pattern ZFG3 and the plurality of first reflective sub-patterns ZFG1 decrease in sequence.

In some embodiments, the reflectivity of the second reflective pattern 4412 is in a range from 80% to 90%. For example, the reflectivity may be 80%, 81%, 82%, 83%, 84%, 85%, 86%, 87%, 88%, 89%, or 90%. In some examples, the transmittance of the second reflective pattern 4412 is in a range from 10% to 20%. For example, the transmittance may be 10%, 11%, 12%, 13%, 14%, 15%, 16%, 17%, 18%, 19%, or 20%.

In some other embodiments, the reflectivity of the first reflective pattern 4411 is in a range from 30% to 40%. For example, the reflectivity may be 30%, 31%, 32%, 33%, 34%, 35%, 36%, 37%, 38%, 39%, or 40%. In some examples, the transmittance of the first reflective pattern 4411 is in a range from 60% to 70%. For example, the transmittance may be 60%, 61%, 62%, 63%, 64%, 65%, 66%, 67%, 68%, 69%, or 70%.

In some other embodiments, the reflectivity of the second reflective pattern 4412 is in a range from 80% to 90%, and the reflectivity of the first reflective pattern 4411 is in a range from 30% to 40%. In some examples, the transmittance of the second reflective pattern 4412 is in a range from 10% to 20%, and the transmittance of the first reflective pattern 4411 is in a range from 60% to 70%. The values of the reflectivity and transmittance of the first reflective pattern and the values of the reflectivity and transmittance of the second reflective pattern may refer to relevant description of the values of the reflectivity and transmittance of the first reflective pattern and the values of the reflectivity and transmittance of the second reflective pattern in the above embodiments.

In some embodiments, the light-emitting module further includes a plurality of circuit units. The plurality of circuit units are disposed on the substrate 410, and the circuit units are coupled to the light-emitting devices 420. The light-emitting module further includes at least one (e.g., one or more) driver chip. The driver chip is disposed on the substrate 410 and is coupled to at least one (e.g., one or more) circuit unit. The driver chip is configured to provide a driving signal to a light-emitting device 420 (i.e., to control the current flowing through a device group QZ), so as to drive the light-emitting device 420 to emit light. For example, the driver chip may be a display drive integrated circuit (DDIC).

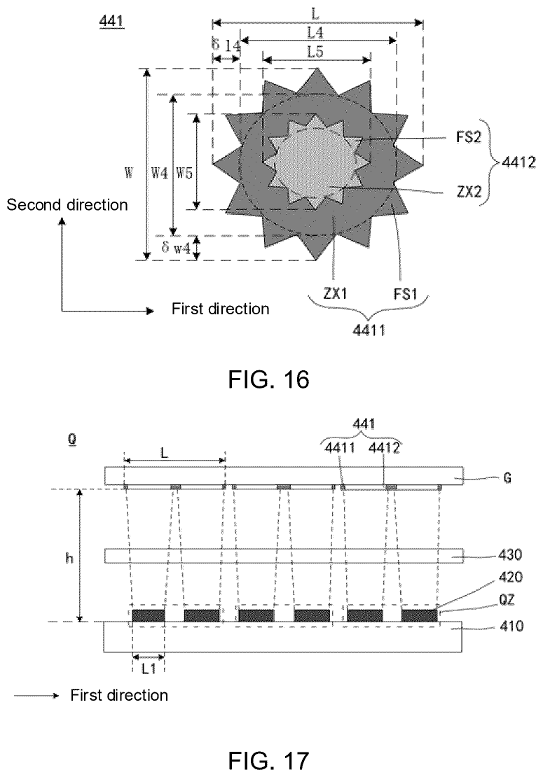

For example, with continued reference to FIGS. 15 and 16, luminances of the plurality of light-emitting devices 420 may be controlled separately. For example, each circuit unit may be coupled to a light-emitting device 420. In some examples, in a case where luminances of the plurality of light-emitting devices 420 may be controlled separately, a reflective unit 441 includes a second reflective pattern 4412 and a first reflective pattern 4411 arranged surrounding the second reflective pattern.

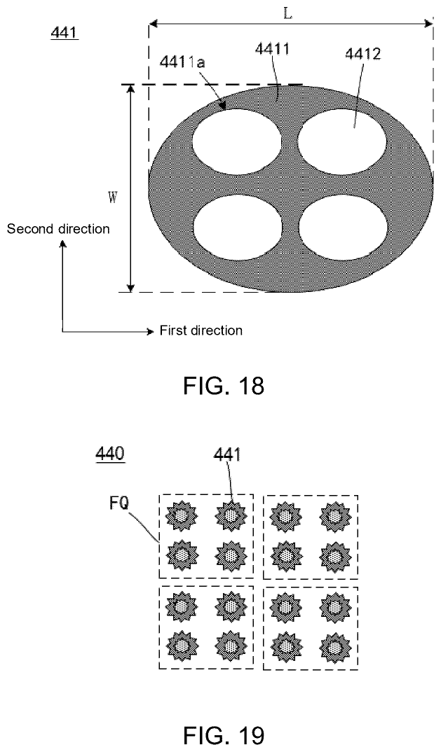

As another example, referring to FIGS. 17 and 18, the plurality of light-emitting devices 420 are divided into a plurality of device groups QZ. A device group QZ includes K (e.g., four, six, eight, nine, ten, or sixteen) light-emitting devices 420 connected in series, where K is greater than 2. For example, as shown in FIG. 17, a device group QZ includes four light-emitting devices 420. In some examples, the plurality of device groups QZ may be arranged in an array. Alternatively, the plurality of device groups QZ may be arranged in any other manners, for example, arranged according to a pattern required to display, and the arrangement is not limited to an array. In some examples, in a reflective unit 441, in a case where the number of hollow regions 4411a is, for example, K, the arrangement of K light-emitting devices 420 in a device group QZ is the same as, for example, the arrangement of the K hollow regions 4411a, and details of which will not be repeated here.

Luminances of the plurality of device groups QZ may be controlled separately; that is, each circuit unit is coupled to a device group QZ, so that the current flowing through different device groups QZ may be controlled individually, and local regional dimming of the light-emitting module 40 can be achieved. In some examples, a circuit unit may be connected to K light-emitting devices 420 in a device group QZ in series. In a possible implementation, a circuit unit may be connected to four, nine, sixteen, or twenty-five light-emitting devices 420 in a device group QZ in series.

In some examples, with continued reference to FIGS. 17 and 18, in the case where the luminances of the plurality of device groups QZ may be controlled separately, a device group QZ corresponds to a reflective unit 441. A reflective unit 441 includes K second reflective patterns 4412 and a first reflective pattern 4411 arranged surrounding the K second reflective patterns 4412. An orthographic projection of each second reflective pattern 4412 in the reflective unit 441 on the substrate 410 overlaps with an orthographic projection of a light-emitting device 420 in a corresponding device group QZ on the substrate 410.

In some other examples, referring to FIG. 19, in the case where the luminances of the plurality of device groups QZ may be controlled separately, a reflective structure 440 may include a plurality of reflective regions FQ. A reflective region FQ includes K reflective units 441. In a case where a device group QZ corresponds to a reflective region FQ, a reflective unit 441 includes a second reflective pattern 4412 and a first reflective pattern 4411 arranged surrounding the second reflective pattern 4412. An orthographic projection of a second reflective pattern 4412 included in each reflective unit 441 in a reflective region FQ on the substrate 410 overlaps with an orthographic projection of a light-emitting device 420 in a corresponding device group QZ on the substrate 410.

In some embodiments, referring to FIGS. 15, 16, 17 and 18, a light-emitting device 420 has a first edge extending in a first direction and a second edge extending in a second direction. The first direction intersects with (e.g., being perpendicular to) the second direction. In a reflective unit 441, at least one second reflective pattern 4412 is arranged in an n*m array, where n is the number of second reflective patterns 4412 included in each row in the first direction and is greater than or equal to 1, m is the number of second reflective patterns 4412 included in each column in the second direction and is greater than or equal to 1. In some examples, in a case where the luminances of the plurality of light-emitting devices 420 may be controlled separately, m=n=1. In some examples, in a case where the luminances of the plurality of device groups QZ may be controlled separately, K=m*n, where m and n are both greater than 1.

A length L of a reflective unit 441 in the first direction and a width W of the reflective unit 441 in the second direction satisfy the following formulas:

$$L = {nL}_{1} + 2 h tan ( θ - 90 ° ) + ( n - 1 ) {L}_{3} + {δ}_{l 2} \qquad ( 1 )$$

$$W = m {W}_{1} + 2 h tan ( θ - 90 ° ) + ( m - 1 ) {W}_{3} + {δ}_{w 2} \qquad ( 2 )$$

L₁ is a length of a light-emitting device 420 in the first direction, and W₁ is a width of the light-emitting device 420 in the second direction; h is a distance between a plane where the light-emitting device 420 is located and a plane where the reflective structure 440 is located; θ is a light-emitting angle of the light-emitting device 420, where θ is in a range from 120° to 150° (e.g., 120°, 125°, 130°, 135°, 140°, 145°, or 150°); L₃ is a distance between adjacent light-emitting devices 420 in the first direction, and W₃ is a distance between adjacent light-emitting devices 420 in the second direction; δₗ₂ and δ_{w2} are constants; δₗ₂ is a tolerance of a reflective unit 441 being disposed on the optical film G in the first direction, and δ_{w2} is a tolerance of the reflective unit 441 being disposed on the optical film G in the second direction.

In some examples, in a case where the number of second reflective patterns in a reflective unit 441 and the number of light-emitting devices in a device group QZ are determined, a distance between adjacent reflective units 441 in the first direction and a distance between adjacent reflective units 441 in the second direction may be determined according to the above relevant description of the reflective unit 441 and the device group QZ. For example, in the case where the calculation formulas for the length L of the reflective unit 441 in the first direction and the width W of the reflective unit 441 in the second direction are determined, a distance d₁ between adjacent reflective units 441 in the first direction and a distance d₂ between adjacent reflective units 441 in the second direction satisfy the following formulas:

$${d}_{1} = {L}_{3} - 2 h tan ( θ - 90 ° ) - {δ}_{l 2} ;$$

$${d}_{2} = {W}_{3} - 2 h tan ( θ - 90 ° ) - {δ}_{w 2} ;$$

In some examples, in the case where a device group QZ includes four light-emitting devices 420 connected in series, it is measured that L₁=0.6 mm, W₁=0.25 mm, θ=120°, L₃=2.1 mm, W₃=2 mm, δₗ₂=0.15 mm, δ_{w2}=0.15 mm. In a case where a quantum dot film 430 exists between the optical film G and the plurality of light-emitting devices 420, h is the thickness of the quantum dot film 430, and h=0.25 mm.

Then, the above parameters are substituted into the formula (1) to calculate the length L of the reflective unit 441 in the first direction, and the result is as follow:

$$L = {nL}_{1} + 2 h tan ( θ - 90 ° ) + ( n - 1 ) {L}_{3} + {δ}_{l 2} = 1.04 mm .$$

Then, the above parameters are substituted into the formula (2) to calculate the width W of the reflective unit 441 in the second direction, and the result is as follow:

$$W = {mW}_{1} + 2 h tan ( θ - 90 ° ) + ( m - 1 ) {W}_{3} + {δ}_{w 2} = 0.69 mm .$$

In a possible implementation, by substituting the above parameters into the calculation formula of distance d and distance d₂, it is obtained that:

$${d}_{1} = {L}_{3} - 2 h tan ( θ - 90 ° ) - {δ}_{l 2} = 1.66 mm , and$$

$${d}_{2} = {W}_{3} - 2 h tan ( θ - 90 ° ) - {δ}_{w 2} = 1.56 mm .$$

For example, with continued reference to FIGS. 17 and 18, in a case where a first reflective pattern 4411 includes a first central portion ZX1 and a plurality of first radiating portions FS1, a length L₄ of the first central portion ZX1 in the first direction and a width W₄ of the first central portion ZX1 in the second direction satisfy the following formulas:

$$\frac{1}{2} {L}_{1} \leq {L}_{4} \leq \frac{3}{4} {L}_{1} ; \frac{1}{2} {W}_{1} \leq {W}_{4} \leq \frac{3}{4} {W}_{1} .$$

In some examples,

$${L}_{4} = \frac{3}{4} {L}_{1} , {W}_{4} = \frac{3}{4} {W}_{1} .$$

For example, in a case of L=1.04 mm and W=0.69 mm,

$${L}_{4} = \frac{3}{4} {L}_{1} = 0.45 mm , and {W}_{4} = \frac{3}{4} {W}_{1} = 0.188 mm .$$

In a first radiating portion FS1, a distance δₗ₄ between an end portion and an root portion in the first direction and a distance δ_{W4} between the end portion and the root portion in the second direction satisfy the following formulas:

$${δ}_{l 4} = ( L - {L}_{4} ) / 2 ; {δ}_{W 4} = ( W - {W}_{4} ) / 2.$$

For example, in a case of L=1.04 mm, W=0.69 mm, L₄=0.45 mm, and W₄=0.188 mm, δₗ₄=(L−L₄)/2=0.295 mm, and δ_{W4}=(W−W₄)/2=0.251 mm.

For example, a length L₅ of the second reflective pattern 4412 in the first direction and a width W₅ of the second reflective pattern 4412 in the second direction satisfy the following formulas:

$$\frac{1}{3} {L}_{4} \leq {L}_{5} \leq \frac{3}{4} {L}_{4} ; \frac{1}{3} {W}_{4} \leq {W}_{5} \leq \frac{3}{4} {W}_{4} .$$

In some examples,

$${L}_{5} = \frac{1}{3} {L}_{4} , and {W}_{5} = \frac{1}{3} {W}_{4} .$$

For example, in a case of L₄=0.5 mm, and W₄=0.188 mm,

$${L}_{5} = \frac{1}{3} {L}_{4} = 0.225 mm , and {W}_{5} = \frac{1}{3} {W}_{4} = 0.094 mm .$$

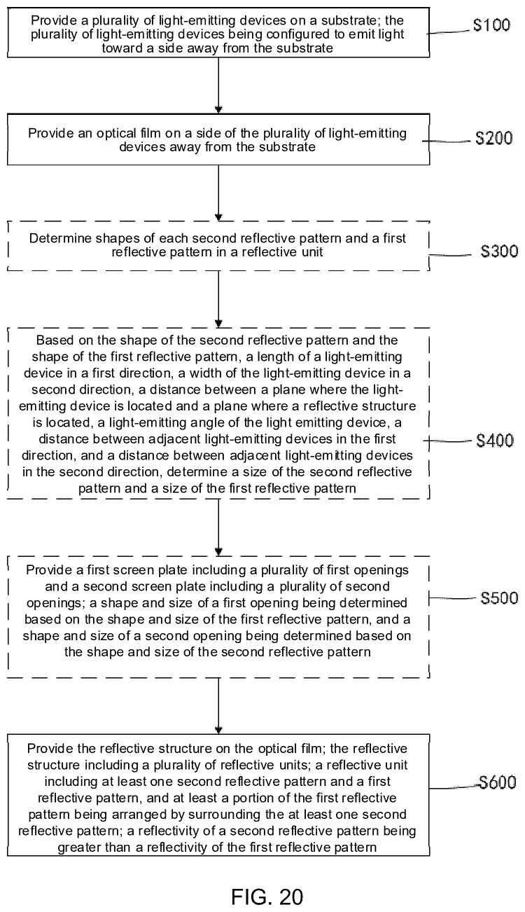

Embodiments of the present disclosure provide an assembling method for a light-emitting module, and referring to FIG. 20, the assembling method includes a step S100, step S200 and step S600.

In the step S100, a plurality of light-emitting devices are provided on a substrate, and the plurality of light-emitting devices are configured to emit light toward a side away from the substrate.

In the step S200, an optical film is provided on a side of the plurality of light-emitting devices away from the substrate.

In the step S600, a reflective structure is provided on the optical film; the reflective structure includes a plurality of reflective units, and a reflective unit includes at least one second reflective pattern and a first reflective pattern formed by surrounding the at least one second reflective pattern; a reflectivity of the second reflective pattern is greater than a reflectivity of the first reflective pattern. An orthographic projection of the second reflective pattern on the substrate overlaps with an orthographic projection of a light-emitting device on the substrate. The second reflective pattern is configured to reflect light emitted by the light-emitting device. The first reflective pattern is configured to reflect light emitted by the light-emitting device. For descriptions of the step S100, step S200, and step S600, reference may be made to the relevant description of the light-emitting module mentioned above, and will not be repeated here.

For a reflective structure being disposed on the optical film, in some examples, as shown in FIG. 4A, the reflective structure is disposed on a side of the optical film G proximate to the substrate 410; for example, as shown in FIG. 4A, the reflective structure is disposed on a side of the diffusion film 450 proximate to the substrate 410; in some other examples, the reflective structure is disposed on a side of the optical film away from the substrate. In some other examples, as shown in FIG. 4B, the reflective structure is disposed inside the optical film; for example, the reflective structure and the optical film may be provided integrally, which may reduce the process compared with providing the reflective structure and the optical film separately. For example, as shown in FIG. 4B, the reflective structure may be disposed inside the diffusion film.

In some examples, the step S200 and step S600 may be adaptively selected according to the needs of process in an assembling method. For example, the step S200 may be performed firstly, and then the step S600 may be performed. As another example, the step S600 may be performed firstly, and then the step S200 may be performed.

With continued reference to FIG. 20, before the step S600, the assembling method for a light-emitting module further includes steps S300 to S500.

In the step S300, shapes of each second reflective pattern and a first reflective pattern in a reflective unit are determined.

In some examples, the shape of the light-emitting device is obtained by an optical equipment. The shape of each second reflective pattern and the shape of the first reflective pattern in the reflective unit are determined based on the shape of the light-emitting device. The light-emitting device may be in a shape of an ellipse, a rectangle, or other regular shapes.

In the step S400, based on the shape of the second reflective pattern and the shape of the first reflective pattern, as well as a length L₁ of the light-emitting device in a first direction, a width W₁ of the light-emitting device in a second direction, a distance h between a plane where the light-emitting device is located and a plane where the reflective structure is located, a light-emitting angle θ of the light-emitting device, a distance L₃ between adjacent light-emitting devices in the first direction, and a distance W₃ between adjacent light-emitting devices in the second direction, a size of the second reflective pattern and a size of the first reflective pattern are determined. This may be understood as that a length L of a reflective unit 441 in the first direction and a width W of the reflective unit 441 in the second direction satisfy the following formulas:

$$L = {nL}_{1} + 2 h tan ( θ - 90 ° ) + ( n - 1 ) {L}_{3} + {δ}_{l 2} ; \qquad ( 1 )$$

$$W = {mW}_{1} + 2 h tan ( θ - 90 ° ) + ( m - 1 ) {W}_{3} + {δ}_{w 2} . \qquad ( 2 )$$

Description of the parameters in the formula (1) and formula (2) may refer to the relevant description of the parameters in the aforementioned formula (1) and formula (2), and will not be repeated here.

In addition, in a case where the first reflective pattern includes a first central portion and first radiating portions, the calculation method for the first reflective pattern may refer to the calculation formula for the first reflective pattern mentioned above. In a case where the second reflective pattern includes a second central portion and second radiating portions, the calculation method for the second reflective pattern may refer to the calculation formula for the second reflective pattern mentioned above. Therefore, details are not repeated here.

In the step S500, a first screen plate including a plurality of first openings and a second screen plate including a plurality of second openings are provided; a shape and size of a first opening are determined based on the shape and size of the first reflective pattern, respectively. For example, the shape and size of the first opening may be determined based on the shape and size of the first opening in Example 1 above, respectively; as another example, the shape and size of the first opening may be determined based on the shape and size of the first opening in Example 2 above, respectively. A shape and size of the second openings are determined based on the shape and size of the second reflective pattern, respectively. For example, the shape and size of the second opening may be determined based on the shape and size of the second opening in Example 1 above, respectively; as another example, the shape and size of the second opening may be determined based on the shape and size of the second opening in Example 2 above, respectively.

In some examples, a first reflective pattern includes a first central portion and first radiating portions. For the relevant description of the first reflective pattern including the first central portion and the first radiating portions, reference may be made to the above relevant description of the first reflective pattern including the first central portion and the first radiating portions. A second reflective pattern includes a second central portion and second radiating portions. For the relevant description of the second reflective pattern including the second central portion and the second radiating portions, reference may be made to the above relevant description of the second reflective pattern including the second central portion and the second radiating portions.

In some examples, first openings of the first screen plate and second openings of the second screen plate are provided based on the number of reflective units, where a number of the first openings and a number of the second openings are both equal to a number of a plurality of second reflective patterns.

In some examples, in a case where the assembling method for a light-emitting module further includes the steps S300 to S500, the step S600 may include the following steps.

Firstly, first reflective patterns 4411 are formed on the optical film G by using the plurality of first openings YWK of the first screen plate YWB.

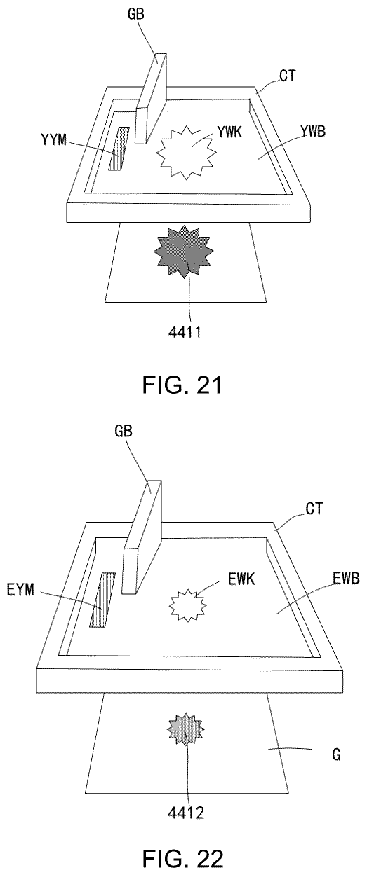

For example, referring to FIG. 21, the first screen plate YWB is fixed on a bottom of an operation frame CT, and a plane where the first screen plate YWB is located is parallel to the operation frame CT. The operation frame CT is adjusted such that the first screen plate YWB is adjusted to a suitable height. An optical film G is placed on a bottom of the first screen plate YWB. A scraper GB is used to print a first ink YYM onto the optical film G through the first opening YWK. After being stationary for a period of time, a first reflective pattern 4411 is formed on the optical film G.

Then, second reflective patterns 4412 are formed on the first reflective pattern 4411 by using the plurality of second openings EWK of the second screen plate EWB.

For example, referring to FIG. 22, the first screen plate is replaced with the second screen plate EWB, the second screen plate EWB is fixed on the bottom of the operation frame CT, and a plane where the second screen plate EWB is located is parallel to the operation frame CT. The operation frame CT is adjusted such that the second screen plate EWB is adjusted to a suitable height. The optical film G on which the first reflective pattern 4411 is provided is placed on a bottom of the second screen plate EWB. The scraper GB is used to print a second ink EYM onto the second reflective pattern 4412 through the second opening EWK. After being stationary for a period of time, a second reflective pattern 4412 is formed on the first reflective pattern 4411. The reflective unit 441 shown in FIG. 7 is thus formed. The second reflective pattern 4412 covers a portion of the first reflective pattern 4411.

For example, the first reflective patterns 4411 are firstly formed on the optical film G by using the plurality of first openings YWK of the first screen plate YWB.

In some other examples, in a case where the assembling method for a light-emitting module further includes the steps S300 to S500, the step S600 may include the following steps.

Firstly, first reflective patterns are formed on the optical film by using the plurality of first openings of the first screen plate, and a first reflective pattern has a hollow region.

For example, the first screen plate is fixed on a bottom of an operation frame, and a plane where the first screen plate is located is parallel to the operation frame. The operation frame is adjusted such that the first screen plate is adjusted to a suitable height. A solid portion that has a same shape as the second reflective pattern is provided in a first opening. An optical film is placed on a bottom of the first screen plate. A scraper is used to print a first ink onto the optical film through the first opening. After being stationary for a period of time, first reflective patterns are formed on the optical film. The first reflective pattern has a hollow region.

Then, second reflective patterns are formed in respective hollow regions by using the plurality of second openings of the second screen plate.

For example, the first screen plate is replaced with the second screen plate, and the second screen plate is fixed on the bottom of the operation frame, and a plane where the second screen plate is located is parallel to the operation frame. The operation frame is adjusted such that the second screen plate is adjusted to a suitable height. The optical film on which the first reflective pattern is provided is placed on a bottom of the second screen plate, and the second screen plate is aligned with the hollow regions. The scraper is used to print a second ink into the hollow region through the second opening. After being stationary for a period of time, a second reflective pattern is formed in the hollow region. The reflective unit shown in FIG. 6 is thus formed.

The aforementioned are only specific embodiments of the present disclosure, but the protection scope of the present disclosure is not limited thereto, variations or substitutions that any person skilled in the art may conceive of within the technical scope revealed by the present disclosure, shall fall within the protection scope of the present disclosure. Therefore, the protection scope of the present disclosure should be subjected to the protection scope of the claims.

1. A light-emitting module, comprising:
a substrate;
a plurality of light-emitting devices disposed on the substrate and configured to emit light toward a side away from the substrate;
an optical film disposed on a side of the plurality of light-emitting devices away from the substrate; and
a reflective structure disposed on the optical film; wherein the reflective structure includes a plurality of reflective units, and a reflective unit includes a first reflective pattern and at least one second reflective pattern; at least a portion of the first reflective pattern is arranged surrounding the at least one second reflective pattern; a reflectivity of a second reflective pattern is greater than or equal to a reflectivity of the first reflective pattern;
wherein an orthographic projection of the second reflective pattern on the substrate overlaps with an orthographic projection of a light-emitting device on the substrate, and the second reflective pattern is configured to reflect light emitted by the light-emitting device; the first reflective pattern is configured to reflect light emitted by the light-emitting device.

2. The light-emitting module according to claim 1, wherein
a transmittance of the second reflective pattern is less than a transmittance of the first reflective pattern.

3. The light-emitting module according to claim 1 or 2, wherein
the light-emitting module has a plurality of light projection regions; wherein a light projection region is a region in a plane where the reflective structure is located and illuminated by light emitted by the light-emitting device; wherein
the second reflective pattern is located in the light projection region, and at least a portion of the first reflective pattern is located in the light projection region.

4. The light-emitting module according to claim 3, wherein
the second reflective pattern covers a geometric center region of the light projection region.

5. The light-emitting module according to claim 3 or 4, wherein
the reflective unit includes a second reflective pattern; in the reflective unit, the first reflective pattern is located in the light projection region; or
the reflective unit includes a plurality of second reflective patterns; in the reflective unit, the first reflective pattern includes a second portion and a plurality of first portions; a first portion is located in the light projection region and arranged surrounding a second reflective pattern; the second portion is located outside the light projection region and connected to the plurality of first portions.

6. The light-emitting module according to any one of claims 1 to 5, wherein
the first reflective pattern has at least one hollow region, and the second reflective pattern is located in a hollow region; or
the first reflective pattern and the second reflective pattern are stacked; the second reflective pattern is closer to the substrate than the first reflective pattern; wherein the first reflective pattern includes a first sub-portion and a second sub-portion; an orthographic projection of the first sub-portion on the substrate coincides with an orthographic projection of the second reflective pattern on the substrate; the second sub-portion is located outside the second reflective pattern and arranged surrounding the first sub-portion.

7. The light-emitting module according to any one of claims 1 to 6, wherein
the first reflective pattern includes a first central portion and a plurality of first radiating portions, the first central portion is arranged surrounding the second reflective pattern, and the plurality of first radiating portions are circumferentially arranged around the first central portion.

8. The light-emitting module according to claim 7, wherein
a number of the plurality of first radiating portions is greater than or equal to five.

9. The light-emitting module according to claim 7 or 8, wherein
a reflectivity of the first central portion is greater than or equal to a reflectivity of a first radiating portion.

10. The light-emitting module according to any one of claims 1 to 9, wherein
the second reflective pattern includes a second central portion and a plurality of second radiating portions, and the plurality of second radiating portions are circumferentially arranged around the second central portion.

11. The light-emitting module according to claim 10, wherein
a reflectivity of the second central portion is greater than or equal to a reflectivity of a second radiating portion.

12. The light-emitting module according to claim 10 or 11, wherein
the first reflective pattern includes a plurality of first radiating portions; a number of the plurality of first radiating portions and a number of the plurality of second radiating portions are same; and extension directions of the first radiating portions are same as extension directions of the plurality of second radiating portions.

13. The light-emitting module according to any one of claims 1 to 12, wherein
the light-emitting device has a first edge extending in a first direction and a second edge extending in a second direction;
in the reflective unit, the at least one second reflective pattern is arranged in an n*m array; n is a number of second reflective patterns included in each row in the first direction, and n is greater than or equal to 1; m is a number of second reflective patterns included in each column in the second direction, and m is greater than or equal to 1;
a length L of the reflective unit in the first direction and a width W of the reflective unit in the second direction satisfy following formulas:
$$L = {nL}_{1} + 2 h tan ( θ - 90 ° ) + ( n - 1 ) {L}_{3} + {δ}_{l 2} ; and$$
$$W = {mW}_{1} + 2 h tan ( θ - 90 ° ) + ( m - 1 ) {W}_{3} + {δ}_{w 2} ;$$
wherein L₁ is a length of the light-emitting device in the first direction, W₁ is a width of the light-emitting device in the second direction; h is a distance between a plane where the light-emitting device is located and a plane where the reflective structure is located; e is a light-emitting angle of the light-emitting device; L₃ is a distance between adjacent light-emitting devices in the first direction, W₃ is a distance between adjacent light-emitting devices in the second direction; δₗ₂ and δ_{w2} are constants.

14. The light-emitting module according to claim 13, wherein
the first reflective pattern includes a first central portion and a plurality of first radiating portions; a first radiating portion has an end portion and a root portion, the root portion is disposed at the first central portion, and the end portion is an end of the root portion opposite to the first central portion;
a length L₄ of the first central portion in the first direction and a width W₄ of the first central portion in the second direction satisfy following formulas:
$$\frac{1}{2} {L}_{1} \leq {L}_{4} \leq \frac{3}{4} {L}_{1} ; \frac{1}{2} {W}_{1} \leq {W}_{4} \leq \frac{3}{4} {W}_{1} ;$$
a length L₅ of the second reflective pattern in the first direction and a width W₅ of the second reflective pattern in the second direction satisfy following formulas:
$$\frac{1}{3} {L}_{4} \leq {L}_{5} \leq \frac{3}{4} {L}_{4} ; \frac{1}{3} {W}_{4} \leq {W}_{5} \leq \frac{3}{4} {W}_{4} ;$$
in the first radiating portion, a distance δₗ₄ between the end portion and the root portion in the first direction and a distance δ_{W4} between the end portion and the root portion in the second direction satisfy following formulas:
$${δ}_{l 4} = ( L - {L}_{4} ) / 2 ; {δ}_{W 4} = ( W - {W}_{4} ) / 2.$$

15. The light-emitting module according to any one of claims 1 to 6 and claim 13, wherein
an outer edge of the first reflective pattern is in a shape of an ellipse or a circle, and the outer edge of the first reflective pattern is an edge of the first reflective pattern away from the second reflective pattern; and/or
the second reflective pattern is in a shape of an ellipse or a circle.

16. The light-emitting module according to any one of claims 1 to 15, wherein
luminances of the plurality of light-emitting devices are controlled separately; the reflective unit includes a first reflective pattern and a second reflective pattern, and at least a portion of the first reflective pattern is arranged surrounding the second reflective pattern.

17. The light-emitting module according to any one of claims 1 to 15, wherein
the plurality of light-emitting devices are divided into a plurality of device groups, and a device group includes K light-emitting devices that are connected in series, and K is greater than 2; wherein
a device group corresponds to a reflective unit; the reflective unit includes a first reflective pattern and K second reflective patterns, and at least a portion of the first reflective pattern is arrange surrounding the K second reflective patterns; wherein an orthographic projection of each second reflective pattern in the reflective unit on the substrate overlaps with an orthographic projection of a light-emitting device in a corresponding device group on the substrate; or
a device group corresponds to K reflective units; a reflective unit includes a first reflective pattern and a second reflective pattern, and at least a portion of the first reflective pattern is arranged surrounding the second reflective pattern; wherein an orthographic projection of a second reflective pattern included in each reflective unit of the K reflective units on the substrate overlaps with an orthographic projection of a light-emitting device in a corresponding device group on the substrate.

18. The light-emitting module according to any one of claims 1 to 17, wherein
the reflective structure is disposed on a side of the optical film proximate to the substrate.

19. The light-emitting module according to any one of claims 1 to 18, wherein
a density of the first reflective pattern is less than or equal to a density of the second reflective pattern.

20. The light-emitting module according to any one of claims 1 to 19, wherein
a thickness of the first reflective pattern is less than or equal to a thickness of the second reflective pattern.

21. The light-emitting module according to any one of claims 1 to 20, wherein
the first reflective pattern is made of a first ink, and the second reflective pattern is made of a second ink.

22. The light-emitting module according to any one of claims 1 to 21, wherein
the optical film is a diffusion film or a light-homogenizing film.

23. The light-emitting module according to any one of claims 1 to 22, wherein
the first reflective pattern includes a plurality of first reflective sub-patterns, and the plurality of first reflective sub-patterns are sequentially arranged surrounding the second reflective pattern; wherein in a direction from the second reflective pattern to the first reflective pattern, transmittances of the plurality of first reflective sub-patterns decrease in sequence; and/or
the second reflective pattern includes a second reflective sub-pattern and at least one third reflective sub-pattern; the at least one third reflective sub-pattern is sequentially arranged surrounding the second reflective sub-pattern; wherein in the direction from the second reflective pattern to the first reflective pattern, transmittances of the second reflective sub-pattern and the at least one third reflective sub-pattern decrease in sequence.

24. The light-emitting module according to any one of claims 1 to 23, wherein
the reflectivity of the second reflective pattern is in a range from 80% to 90%; and/or
the reflectivity of the first reflective pattern is in a range from 30% to 40%.

25. An assembling method for a light-emitting module, comprising:
providing a plurality of light-emitting devices on a substrate, wherein the plurality of light-emitting devices are configured to emit light toward a side away from the substrate;
providing an optical film on a side of the plurality of light-emitting devices away from the substrate; and
providing a reflective structure on the optical film, wherein the reflective structure includes a plurality of reflective units; a reflective unit includes a first reflective pattern and at least one second reflective pattern, and at least a portion of the first reflective pattern is arranged by surrounding the at least one second reflective pattern; a reflectivity of a second reflective pattern is greater than a reflectivity of the first reflective pattern;
wherein an orthographic projection of the second reflective pattern on the substrate overlaps with an orthographic projection of a light-emitting device on the substrate, the second reflective pattern is configured to reflect light emitted by the light-emitting device, and the first reflective pattern is configured to reflect light emitted by the light-emitting device.

26. The assembling method for a light-emitting module according to claim 25, wherein before the step of providing the reflective structure on the optical film, the assembling method for the light-emitting module further comprises:
determining shapes of each second reflective pattern and a first reflective pattern in the reflective unit;
based on the shape of the second reflective pattern and the shape of the first reflective pattern, a length L₁ of the light-emitting device in a first direction, a width W₁ of the light-emitting device in a second direction, a distance h between a plane where the light-emitting device is located and a plane where the reflective structure is located, a light-emitting angle θ of the light-emitting device, a distance L₃ between adjacent light-emitting devices in the first direction, and a distance W₃ between adjacent light-emitting devices in the second direction, determining a size of the second reflective pattern and a size of the first reflective pattern; and
providing a first screen plate including a plurality of first openings and a second screen plate including a plurality of second openings; wherein a shape and size of a first opening is determined based on the shape and size of the first reflective pattern, respectively, and a shape and size of a second opening is determined based on the shape and size of the second reflective pattern, respectively;
the step of providing the reflective structure on the optical film includes:
forming a plurality of first reflective patterns on the optical film by using the plurality of first openings of the first screen plate; and forming a plurality of second reflective patterns on the optical film by using the plurality of second openings of the second screen plate.

27. A display apparatus, comprising:
the light-emitting module according to any one of claims 1 to 24.
